(19) United States
(12) Patent Application Publication
(10) Pub. No.: US 2025/0271650 A1
(43) Pub. Date: Aug. 28, 2025

(54) CHANGING OPTICAL SYSTEM PROPERTIES DURING REPAIR

(71) Applicant: Orbotech Ltd., Yavne (IL)

(72) Inventor: Oded Mor, Shoham (IL)

(21) Appl. No.: 18/585,942

(22) Filed: Feb. 23, 2024

(51) Int. Cl. G02B 19/00; G02B 26/10; H05K 3/22

(52) U.S. Cl. CPC G02B 19/0047; G02B 19/0014; H05K 3/225; G02B 26/101; H05K 2203/107

(57) ABSTRACT

A repair system changes optical properties during repair. The optical properties may be changed based on the dimensions of each defect as the defect is repaired. Changing the optical properties based on the dimensions of each defect as opposed to presetting the optical properties based on the dimensions of finest feature reduces the repair time for larger defects while enabling repairing the finest features.

### TECHNICAL FIELD

The present invention generally relates to printed circuits, and more particularly to repairing printed circuits.

### BACKGROUND

Printed circuits may include defects during manufacturing, such as excess material defects (e.g., short defects) or missing material defects (e.g., open defects). Printed circuits with defects are either discarded or repaired. Repairing the defects is desirable to improve yield and reduce scrap. Therefore, it would be advantageous to provide a device, system, and method that cures the shortcomings described above.

### SUMMARY

A repair system is described, in accordance with one or more embodiments of the present disclosure. The repair system may include: a light source, wherein the light source is configured to generate illumination; a laser generator, wherein the laser generator is configured to generate laser light; a two-axis scanner, wherein the two-axis scanner steers the laser light; a sample stage, wherein the sample stage is configured to support a sample; an objective lens, wherein the laser light is configured to pass through the objective lens to the sample to perform a repair of a defect located at a defect location on the sample; a detector, wherein the detector is configured to generate image data associated with the sample based on collected light, wherein the collected light reflects from the sample, through the objective lens, to the detector; and a controller including one or more processors configured to execute program instructions maintained on a memory medium, the program instructions causing the controller to: change one or more optical properties of at least one of the illumination, the laser light, or the collected light during the repair of the defect.

In some aspects, the defect is an excess material defect including an excess solid material; wherein the laser light repairs the excess material defect by ablating the excess solid material.

In some aspects, the program instructions cause the controller to change the one or more optical properties during the repair of the defect based on feedback from the image data.

In some aspects, the one or more optical properties of the laser light include at least a spot size of the laser light, wherein the repair system is configured to perform a first stage of repair of the defect using a first spot size and a second stage of repair of the defect using a second spot size.

In some aspects, the repair system changes between the first spot size and the second spot size by changing at least one of the objective lens, a magnification of the objective lens, a focus position, a position of a variable beam expander, or an iris diameter.

In some aspects, the repair system includes an objective lens turret including a plurality of objective lenses, wherein the objective lens is one of the plurality of objective lenses, wherein the controller is configured to cause the objective lens turret to change between the plurality of objective lenses.

In some aspects, the repair system includes a zoom motor, wherein the zoom motor is coupled to the objective lens, wherein the zoom motor controls the magnification of the objective lens.

In some aspects, the program instructions cause the controller to change the spot size during the repair of the defect based on a closed loop condition including a sharpness of the defect in the image data.

In some aspects, the one or more optical properties of the laser light include at least a fluence of the laser light.

In some aspects, the one or more optical properties of the illumination include at least one of an incidence angle of the illumination or a collection angle of illumination reflected from the sample.

In some aspects, the one or more optical properties of the laser light include at least a waist position of the laser light.

In some aspects, the controller is configured to direct the waist position of the laser light to follow along a height profile of the defect.

In some aspects, the one or more optical properties of the laser light include the waist position and a fluence of the laser light.

In some aspects, the controller is configured to preset the one or more optical properties based on a finest feature in a design file.

In some aspects, the controller is configured to preset the one or more optical properties based on an expected size of the defect according to a design resolution in a design file at the defect location.

In some aspects, the controller presets the one or more optical properties before the detector generates the image data.

In some aspects, the controller changes the one or more optical properties on a pulse-to-pulse basis.

In some aspects, the memory medium maintains a design file and a defect report, wherein the design file includes two-dimensional data, wherein the repair system is configured to iteratively reach the defect location, acquire the image data at the defect location, identify the defect, set the one or more optical properties based on the defect identified, and repair the defect for each known defect in the defect report.

In some aspects, the memory medium maintains a design file and a defect report, wherein the design file includes two-dimensional data, wherein the repair system is configured to iteratively check a design resolution in the design file at the defect location, preset the one or more optical properties according to the design resolution in the design file at the defect location, reach the defect location, acquire the image data at the defect location, identify the defect in the image data, set the one or more optical properties based on the defect identified if needed, and repair the defect for each known defect in the defect report.

In some aspects, the memory medium maintains a design file and a defect report, wherein the design file includes two-dimensional data, wherein the repair system is configured to iteratively reach the defect location on the sample, acquire the image data at the defect location, identify the defect, set the one or more optical properties based on the defect identified, perform a first stage of defect repair, change the one or more optical properties, and perform a second stage of repair for each known defect in the defect report.

In some aspects, the one or more optical properties include at least a spot size of the laser light, wherein the controller is configured to set the spot size of the laser light to a first spot size, wherein the repair system performs the first stage of defect repair using the first spot size, wherein the controller changes the spot size of the laser light to a second spot size, wherein the repair system performs the second stage using the second spot size.

In some aspects, the repair system scans the laser light along a center of the defect in the first stage, wherein the repair system scans the laser light along an exterior perimeter of the defect in the second stage.

In some aspects, the repair system does not scan the laser light along the exterior perimeter in the first stage.

In some aspects, the defect is disposed between a pair of conductors, wherein a spot size of the laser light is changed based on at least one of a space width between the pair of conductors and a line width of at least one of the pair of conductors.

In some aspects, the repair system is configured to find at least one of the space width or the line width based on at least one of a design file or the image data.

In some aspects, the collected light reflecting from the sample includes light emitted by the sample following excitation by the illumination or by the laser light.

In some aspects, the illumination and the laser light are configured to pass through the objective lens to the sample.

In some aspects, the illumination is directed to the sample in a darkfield configuration.

A method is described, in accordance with one or more embodiments of the present disclosure. The method may include: changing one or more optical properties of at least one of an illumination, a laser light, or a collected light during a repair of a defect by a controller of a repair system, the repair system comprising a light source, wherein the light source is configured to generate the illumination; a laser generator, wherein the laser generator is configured to generate the laser light; a two-axis scanner, wherein the two-axis scanner steers the laser light; a sample stage, wherein the sample stage is configured to support a sample; an objective lens, wherein the laser light is configured to pass through the objective lens to the sample to perform the repair of the defect located at a defect location on the sample; a detector, wherein the detector is configured to generate image data associated with the sample based on the collected light, wherein the collected light reflects from the sample, through the objective lens, to the detector; and the controller comprising one or more processors configured to execute program instructions maintained on a memory medium, the program instructions causing the controller to change the one or more optical properties.

### BRIEF DESCRIPTION OF THE DRAWINGS

The numerous advantages of the disclosure may be better understood by those skilled in the art by reference to the accompanying figures in which:

FIG. 1 depicts a block diagram of a repair system, in accordance with one or more embodiments of the present disclosure.

FIG. 2 depicts a flow diagram of a method, in accordance with one or more embodiments of the present disclosure.

FIG. 3 depicts a flow diagram of a method, in accordance with one or more embodiments of the present disclosure.

FIGS. 4A-4C depicts a top view of a sample with a laser spot size which is changed based on line spacing, in accordance with one or more embodiments of the present disclosure.

FIG. 5 depicts a flow diagram of a method, in accordance with one or more embodiments of the present disclosure.

FIGS. 6A-6E depict a top view of a sample, in accordance with one or more embodiments of the present disclosure.

FIGS. 7A-7E, 8, and 9 depict a side view of a sample, in accordance with one or more embodiments of the present disclosure.

FIGS. 10A-10F depict a block diagram of a repair system, in accordance with one or more embodiments of the present disclosure.

### DETAILED DESCRIPTION OF THE INVENTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

A repair system uses a laser to repair material defects, such as excess material defects and open defects. The repair system sets the optical properties to repair the finest features of the printed circuits. Printed circuits may include at least a line having a line width, also called a trace width. The line width of printed circuits is reduced as the density of the printed circuits is increased. The repair system must be configured with optical properties to repair the finest line widths of the printed circuits. In embodiments, the repair system may automatically determine the finest feature in the design file and set the optical properties according to finest feature. Setting the optical properties according to the finest features enables the repair system to repair all the defects of the printed circuit.

Printed circuits typically have multiple line widths. For example, in packaging applications, the line widths are smaller in areas for semiconductor chip and the line widths fans out to larger widths away from the semiconductor chips. Only a portion of the printed circuits has the finest features. Setting the optical properties according to the finest features causes the repair system to increase the repair time for larger line widths.

Embodiments of the present disclosure are generally directed to changing optical properties during repair. The optical properties are changed based on the dimensions of each defect and optionally neighboring conductors, as the defect is repaired. Changing the optical properties based on the dimensions of each defect as opposed to presetting the optical properties based on the dimensions of finest feature reduces the repair time for larger defects while enabling repairing the finest features.

U.S. Pat. No. 8,290,239, titled “Automatic repair of electric circuits”; U.S. Patent Publication Number 2006/0226865, titled “Automatic defect repair system”; Chinese Patent Publication Number 114521061, titled “Method and equipment for repairing short circuit of printed circuit board by using laser”; are each incorporated herein by reference in the entirety.

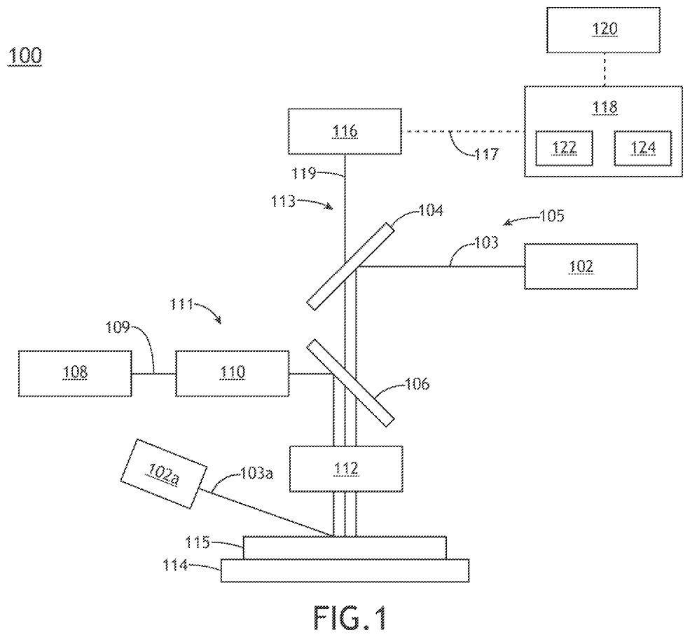

Referring now to FIG. 1, a repair system 100 is described, in accordance with one or more embodiments of the present disclosure. The repair system 100 may be a repair tool. The repair system 100 includes one or more components, such as, but not limited to, a light source 102, beam splitter 104, beam splitter 106, laser generator 108, two-axis scanner 110 (such as a fast-steering mirror, a pair of Galvanometer scanners, two-axis acousto-optic deflectors, and the like), objective lens 112, sample stage 114, detector 116, controller 118, user interface 120, and the like.

In embodiments, the repair system 100 includes one or more sub-systems. The light source 102, the beam splitter 104, the beam splitter 106, and the objective lens 112 may be considered an illumination sub-system. The laser generator 108, the two-axis scanner 110, the beam splitter 106, and the objective lens 112 may be considered a laser processing sub-system. The objective lens 112, the beam splitter 106, the beam splitter 104, and the detector 116 may be considered an image acquisition sub-system. The illumination sub-system, the laser processing sub-system, and the image acquisition sub-system may share a common optical path. For example, the illumination sub-system, the laser processing sub-system, and the image acquisition sub-system may include the objective lens 112 in common. By way of another example, the laser processing sub-system and the image acquisition sub-system may share the beam splitter 106 in common. In this regard, the repair system 100 may be considered an integrated repair and vision system.

The repair system 100 may include the light source 102. The light source 102 may also be an illumination source. The light source 102 may generate illumination 103. The illumination 103 may include one or more selected wavelengths of light including, but not limited to, vacuum ultraviolet radiation (VUV), deep ultraviolet radiation (DUV), ultraviolet (UV) radiation, visible radiation, or infrared (IR) radiation. The illumination 103 may include any range of selected wavelengths. In embodiments, the light source 102 may include a spectrally-tunable illumination source to generate illumination 103 having a tunable spectrum. The illumination 103 includes one or more optical properties. For example, the optical properties of the illumination 103 may include, but are not limited to, an incidence angle, a collection angle of illumination reflected from the sample 115, one or more wavelengths, and the like.

The repair system 100 may include the beam splitter 104. The beam splitter 104 may also be a beam combiner, a splitter/combiner, or the like. In embodiments, the light source 102 may direct the illumination 103 to the beam splitter 104 via an illumination path 105. The illumination 103 from the light source 102 may pass through the beam splitter 104. The illumination 103 may be on-axis after passing through the beam splitter 104. For example, the beam splitter 104 may combine the illumination 103 from the light source 102 such that the illumination 103 is on-axis with the detector 116 and/or the sample 115. The illumination 103 which is on-axis with the detector 116 and/or the sample 115 may be in brightfield configuration. In embodiments, the illumination 103 may be made parallel to the optical axis of the objective lens 112 by the beam splitter 104. The beam splitter 104 may be oriented such that the light source 102 may simultaneously direct the illumination 103 to the sample 115 and such that the detector may collect illumination reflected from the sample 115.

Although the repair system 100 is described as including the beam splitter 104 and the illumination 103 is described as on-axis or in the brightfield configuration, this is not intended as a limitation of the present disclosure. In embodiments, the repair system 100 may include a light source 102a. The discussion of the light source 102 is incorporated herein by reference as to the light source 102a. The light source 102a may generate illumination 103a. The discussion of the illumination 103 is incorporated herein by reference as to the illumination 103a. The illumination 103a may be off-axis. The illumination 103a may be directed to the sample 115 in a darkfield configuration. The repair system 100 may include the light source 102 which generates the illumination 103 and/or the light source 102a which generates the illumination 103a. Thus, the repair system 100 may include a brightfield configuration and/or a darkfield configuration.

The repair system 100 may include the laser generator 108. The laser generator 108 generates laser light 109. The laser generator 108 may be a pulsed laser generator and the laser light 109 may be a pulsed beam.

The laser light 109 may include one or more optical properties. The optical properties may include optical properties of the laser light 109 per se and/or of the beam of the laser light 109 as manipulated by the various optical elements of the repair system 100 (e.g., the objective lens 112, etc.). For example, the optical properties of the laser light 109 may include a spot size, fluence, waist position, beam profile, wavelength, Rayleigh length, energy, defocus, diameter, and the like.

The laser light 109 may include a selected spot size. The spot size may also be a waist radius, spot area, a minimum spot size, a focal spot, w₀, or the like. The objective lens 112 may focus the laser light 109 to the spot size. The spot size may be the minimum beam radius of the laser light 109. The spot size may be located at the waist position. The beam radius of the laser light 109 may increase away from the waist position.

The laser light 109 may include a selected fluence. The fluence may be dependent upon the spot size and the laser energy. For example, the fluence may be the laser energy per unit area of the spot size. The fluence may be a peak fluence or a fluence at the waist position. The fluence may control the depth of ablation of the laser light 109 into the material. Lasers with higher fluence may ablate more material.

The laser light 109 may include a selected waist position. The waist position may be the position where the spot size is located. The two-axis scanner 110 may laterally steer the waist position.

The laser light 109 may include a selected beam profile. The beam profile may include a conical cross-section. In embodiments, the laser light 109 may have a Gaussian distribution. In embodiments, the laser light 109 may have a non-Gaussian distribution, such as a flat-top spot, a uniform intensity spot, or the like.

The laser light 109 may be characterized by at least one wavelength. The laser light 109 may include any wavelength, such as, but not limited to, 266 nm, 355 nm, 532 nm, 1064 nm, or the like. In embodiments, the laser generator 108 may be a tunable laser generator. For example, the laser generator 108 may tune the laser light 109 between multiple wavelengths.

The laser light 109 may include a selected Rayleigh length. The Rayleigh length may be the distance from the waist position where beam radius is minimal to a position where the radius of the laser light 109 is increased by a factor square root of 2.

The repair system 100 may include the two-axis scanner 110. The two-axis scanner 110 may be a two-axis scanner, two-axis fast steering mirror (FSM), a pair of single-axis galvanometer scanners, or the like. The laser light 109 may pass through the two-axis scanner 110. The two-axis scanner 110 may steer the laser light 109 over the area of the defect on the sample 115. The two-axis scanner may scan over a field-of-view. For example, the field-of-view may be a circle with diameter on the order of 1 to 1000 micrometers, or less. The controller 118 may provide control signals operative to manipulate the two-axis scanner 110 to steer the laser light 109. The two-axis scanner 110 may steer the laser light 109 in two dimensions (X-Y dimensions). The two-axis scanner 110 may have independent control of X-Y positioning. The laser light 109 may be steered to impinge on defects disposed on the sample 115, thereby performing a laser repair operation, such as ablation of spurious conductor deposits.

The repair system 100 may include the beam splitter 106. In embodiments, the laser generator 108 may direct the laser light 109 to the beam splitter 106. The laser light 109 may be directed to the beam splitter 106 via a laser path 111. The laser light 109 from the laser generator 108 may pass through the beam splitter 106. The laser light 109 may be on-axis and/or off-axis. For example, the beam splitter 106 may combine the laser light 109 from the laser generator 108 with collected light 119. The beam splitter 106 may also combine the optical path of the laser light 109 and the on-axis illumination 103.

The repair system 100 may include the objective lens 112. The objective lens 112 may include one or more optical elements, which may be reflective, refractive, or both. The objective lens 112 may include any suitable lens. In embodiments, the objective lens 112 may include an F-theta lens. The illumination 103 and the laser light 109 may share the objective lens 112. The illumination 103 and the laser light 109 may pass through the objective lens 112. The objective lens 112 may direct the illumination 103 and the laser light 109 onto the sample 115. In particular, the objective lens 112 may direct the laser light 109 to the material defects on the sample 115. A (partially) common optical path for the illumination 103 and the laser light 109 may be used to enable accurate calibration and avoid positioning errors. Thus, the laser light 109 is configured to pass through the objective lens 112 to the sample 115 to perform a repair of a defect located at a defect location on the sample 115.

The repair system 100 may include an optional medium between the objective lens 112 and the sample 115. The optical medium may include any suitable optical medium, such as, but not limited to, air, an immersion fluid (e.g., water, oil, etc.), and the like.

The repair system 100 may include the sample stage 114. The sample stage 114 may support the sample 115. The repair system 100 may be configured to translate various of the sub-systems relative to the sample stage 114 and the sample 115. For example, the sample stage 114 may be configured to control the X-Y positioning of the sample 115 relative to the illumination 103, the illumination 103a, and/or the laser light 109. In embodiments, the sample stage 114 may also control the Z-positioning of the sample 115 relative to the illumination 103, the illumination 103a, and/or the laser light 109.

The sample 115 may include defects. The defects may include excess material defects (e.g., short defects) and/or missing material defects (e.g., open defects). The excess material defect may be an excess solid material, such as an excess of conductive material or an excess of insulating material. The excess material defect may be an excess of a conductive material, such as copper, or an excess of an insulating material such as substrate, solder resist, or solder mask. The defects may be protrusions, nicks, islands, shorts, opens, and the like. The repair system 100 may be used to repair defects of the sample 115. For example, the laser light 109 may ablate the excess material defect to repair the sample 115. The laser light 109 may repair the excess material defect by ablating the excess solid material.

In embodiments, the repair system 100 may include collected light 119. The illumination 103 and/or the illumination 103a may reflect from the sample 115 as the collected light 119. The laser light 109 may also reflect from the sample 115 as the collected light 119. The collected light 119 reflecting from the sample 115 may also include fluorescence emitted from the sample 115 following excitation by the illumination 103, illumination 103a, and/or laser light 109. The illumination 103, the illumination 103a, and/or the laser light 109 may cause a portion of the sample 115 to fluoresce. Thus, the collected light 119 may include a specular reflection of on-axis illumination, diffuse reflection of off-axis illumination, reflected laser light, and/or fluorescence emitted by the sample 115 upon excitation. The collected light 119 may be different than the illumination 103, the illumination 103a, and/or the laser light 109 in spectrum, optical power, and/or direction.

The collected light 119 may reflect from the sample 115 along a collection path 113. The collected light 119 may reflect from the sample 115 through the objective lens 112, the beam splitter 106, and/or the beam splitter 104. The collected light 119 reflects from the sample 115 to the detector 116.

The repair system 100 may include the detector 116. The detector 116 may be configured to capture the collected light 119. In this regard, the detector 116 may receive the collected light 119 reflected or scattered (e.g., via specular reflection, diffuse reflection, and the like) from the sample 115. The detector 116 may be configured to generate image data 117 associated with the sample 115 based on the collected light 119. The detector 116 may be a camera. The detector 116 may include any type of optical detector suitable for measuring illumination received from the sample 115. For example, the detector 116 may include, but is not limited to, a CCD detector, a TDI detector, a photomultiplier tube (PMT), an avalanche photodiode (APD), a complementary metal-oxide-semiconductor (CMOS) sensor, or the like.

The image data 117 may include a reflectance image of the sample 115 or an image of fluorescence emitted by the sample. A reflectance image may be, for example, an image of the defect being scanned by the laser light 109. Different reflectance images may be acquired under different configurations of the illumination 103, the illumination 103a, and/or the laser light 109.

The repair system 100 may include the controller 118. The controller 118 may include one or more processors 122 configured to execute program instructions maintained on memory medium 124. In this regard, the one or more processors 122 of controller 118 may execute any of the various process steps described throughout the present disclosure.

In embodiments, the memory medium 124 may include a design file. The design file may represent the design to which the sample 115 should adhere. The design file may include a design resolution of a line. The design resolution may include two-dimensional (2D) data about the line. For instance, the design resolution may include a line width. The design resolution may also include three-dimensional (3D) data about the line. For instance, the design resolution may include a line thickness. The design file may also include a thickness of the substrate. The design file may be derived from computer aided manufacturing (CAM). The design file may be a CAM file or CAM data. The design file may include a map of contours, namely edges between conductor and substrate, corresponding to the electrical circuit to be inspected.

In embodiments, the controller 118 may find the finest feature of the design of sample 115. The controller 118 may find the finest feature by a procedure such as computer aided manufacturing (CAM) learning. The controller 118 may process the design file to understand what is in the design. The controller 118 may understand what portions of the design are lines, pads, vias, and the like. For example, the controller 118 may measure the nearest neighbor conductors for every point in the design file. Coarser designs may have a further distance to the nearest neighbor conductors. Finer designs may have smaller distances to the nearest neighbor conductors.

In embodiments, the controller 118 may be configured to change one or more optical properties of the illumination 103, illumination 103a, the laser light 109, and/or the collected light 119 based on feedback from the image data 117 from the detector 116. The controller 118 may change one or more components of the illumination path 105, the laser path 111, and/or the collection path 113 to change the optical properties of illumination 103, illumination 103a, the laser light 109, and/or the collected light 119. For example, the controller 118 may control the optical properties of the laser light 109 to change any of the spot size, fluence, waist position, beam profile, wavelength, Rayleigh length, and the like. The controller 118 may change the optical properties of the laser light 109 by moving the objective lens 112, changing a zoom setting of the objective lens 112, changing the objective lens 112, varying a numerical aperture of the objective lens 112, varying a beam diameter of the laser light 109, changing a spot energy profile of the laser light 109, changing the wavelength of the laser light 109, or the like. Similarly, the controller 118 may control optical properties of the illumination 103, illumination 103a, and/or collected light 119 such as a field-of-view, focus, and the like. The controller 118 may change the optical properties of the illumination 103, illumination 103a, the laser light 109, and/or the collected light 119 during the repair of the defects.

In embodiments, the controller 118 may be configured to change the optical properties of the laser light 109 according to the finest features of the sample 115. Although the controller 118 is described as setting the optical properties of the laser light 109 according to the finest features of the sample 115, this is not intended as a limitation of the present disclosure.

In embodiments, the memory medium 124 may include a defect report. The controller 118 may receive the defect report from an automated optical inspection (AOI) system, or the like, and store the defect report in the memory medium 124. The AOI system may be an upstream tool that may inspect the sample 115 and may determine where the defect candidates are located. The defect report may also be referred to as an AOI report or the like. The defect report may include a location of one or more defects on the sample 115. The defect report may indicate defects on the sample 115. The defect report may include locations of the defects, and may include repair-assisting information such as type of defect, quantity of laser pulses to be delivered, laser power, and the like. Although the defect report is described as including the quantity of laser pulses to be delivered and the laser power, this is not intended as a limitation of the present disclosure. The quantity of laser pulses to be delivered, the laser power, and the like may be part of a repair recipe.

The controller 118 may be communicatively coupled to the detector 116. The controller 118 may be configured to receive data including, but not limited to, image data 117 from the detector 116. The controller 118 may cause the detector 116 to generate the image data 117 of the location of one or more defects on the sample 115. For example, the controller 118 may cause the detector 116 to generate the image data 117 of the location based on the defect report.

In embodiments, the controller 118 may change the optical properties of the laser light 109 during repair of defects of the sample 115. For example, the controller 118 may change the optical properties of the laser light 109 during repair of the sample 115 based on a size of the defect in the image data 117. By way of another example, the controller 118 may preset the optical properties of the laser light 109 based on an expected size of the defect according to the design resolution in the design file at the defect location.

In embodiments, the repair system 100 may configure one or more of the optical properties of the laser light 109 on a pulse-to-pulse basis. For example, the repair system 100 may configure energy, defocus, and/or diameter on a pulse-to-pulse basis. For instance, laser spots directed to impinge adjacent to “reference” conductors may have a different energy than laser spots directed to impinge farther from “reference” conductors. In embodiments, the repair system 100 may perform per-spot focusing. The repair system 100 may perform per-spot focusing by moving the objective lens 112, moving the sample 115, a variable-focus optical element, and the like. Configuring the optical properties on the pulse-by-pulse basis may include changing the properties every pulse, every other pulse, or a slower rate thereof.

In embodiments, the repair system 100 may configure one or more of the optical properties of the laser light 109 iteratively during repair of the defect. The repair system 100 may deliver the laser light 109 to the defect location. The fluence of the laser light 109 may be selected so that the laser light 109 does not damage the substrate of the sample 115, even if the laser light 109 does not fully remove the excess material upon the initial application of laser light 109 to the excess material. Following completion of an initial repair operation, the repair system 100 may acquire additional image data 117 of the defect location. The repair system 100 may determine that some portion of the defect is still present at the defect location. For example, the repair system 100 may determine that the portion of the defect is present at the defect location in the image data 117 (e.g., from a fluorescence image). The repair system 100 may adjust the optical properties of the laser light 109 and may deliver the laser light 109 to the defect location using the adjusted optical properties. The process of verifying the presence of a defect, adjusting the optical properties, and automatically performing a repair operation may be repeated until the controller 118 determines that the defect has been repaired. The controller 118 may determine that the defect has been repaired by detecting that the defect is no longer present at the defect location in the image data 117 (e.g., from a fluorescence image). Upon determining that the defect has been repaired, the repair system 100 may reposition to a next defect location.

In embodiments, the repair system 100 may include the user interface 120. The user interface 120 may be communicatively coupled to the controller 118. In embodiments, the user interface 120 may include, but is not limited to, one or more desktops, laptops, tablets, and the like. In embodiments, the user interface 120 may include a display used to display data of the system 100 to a user. The display of the user interface 120 may include any display known in the art. For example, the display may include, but is not limited to, a liquid crystal display (LCD), an organic light-emitting diode (OLED) based display, or a CRT display. Those skilled in the art should recognize that any display device capable of integration with a user interface 120 is suitable for implementation in the present disclosure. In another embodiment, a user may input selections and/or instructions responsive to data displayed to the user via a user input device of the user interface 120.

The illumination path 105, laser path 111, and/or the collection path 113 may include additional illumination optical components (not depicted). The additional illumination optical components may be suitable for modifying and/or conditioning the illumination 103, illumination 103a, laser light 109, and/or the collected light 119. For example, the one or more illumination optical components may include, but are not limited to, objective lens turret, one or more iris, one or more variable beam expanders, one or more diffractive optical elements, one or more lenses, one or more polarizers, one or more filters, one or more beam splitters, one or more diffusers, one or more homogenizers, one or more apodizers, one or more shapers, one or more shutters (e.g., mechanical shutters, electro-optical shutters, acousto-optical shutters, or the like), one or more aperture stops, and/or one or more field stops.

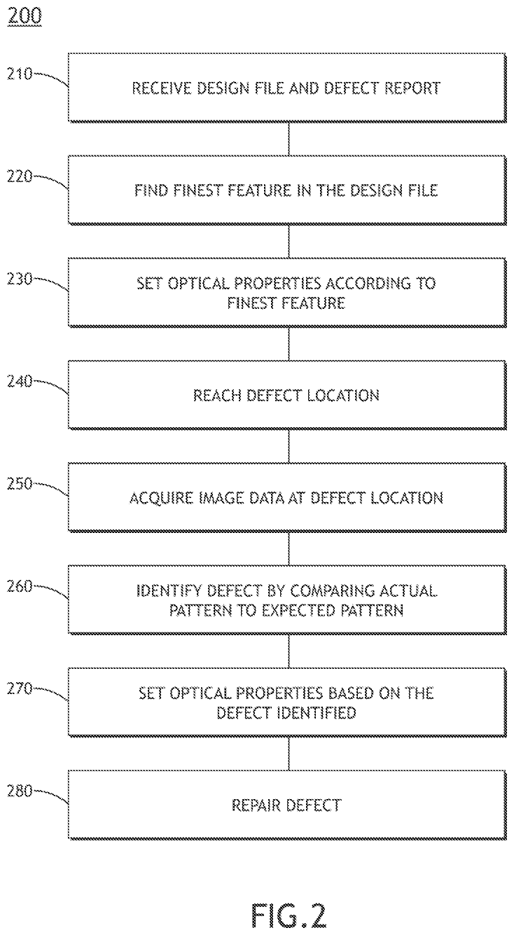

Referring now to FIG. 2, a method 200 is described, in accordance with one or more embodiments of the present disclosure. The method 200 is a method of setting repair properties according to actual defect. The embodiments and the enabling technologies described previously herein in the context of the repair system 100 should be interpreted to extend to the method. It is further noted, however, that the method is not limited to the architecture of the repair system 100.

In a step 210, the controller 118 may receive a design file and defect report of the sample 115. The design file may be a panel design.

In a step 220, the controller 118 may find a finest feature in the design file. The finest feature may have a design resolution (e.g., line width and/or space width between conductors) which is the finest of all features in the design file. The finest feature may be the likeliest defect that the repair system 100 needs to repair.

In a step 230, the controller 118 may set the optical properties of the laser light 109 according to the finest feature. In embodiments, finding the finest features in the design file and setting the optical properties according to the finest feature may be considered optional steps in the method 200. However, presetting the optical properties according to the finest feature before reaching the defect location may shorten repair time, because most defects are likely at the finest features.

In a step 240, the repair system 100 may reach a defect location on the sample 115. The repair system 100 may reach the defect location by the sample stage 114 positioning the sample 115 such that the defect of the sample is within the field-of-view of the detector 116. The location of the defect may be known from the defect report.

In a step 250, the detector 116 may acquire the image data 117 at the defect location. The image data may include a panel image, or the like.

In a step 260, the controller 118 may identify the defect by comparing the actual pattern at the defect location in the image data 117 to the expected pattern at the defect location in the design file. For example, the controller 118 may identify dimensions (e.g., a size (X-Y) and a height) of the defect or the like. After acquiring the image data 117, the controller 118 may verify that the finest feature from the design file matches the actual defect resolution in the image data 117 and then does not need to make additional changes to the optical properties. Presetting the optical properties according to the finest feature may be beneficial to save time during the repair process. For example, the defects with the finest feature may be most likely to need repair, such that presetting to the finest feature may save time. Thus, the repair system may be preset upon reaching the defect location without needing to adjust the optical system properties to match the finest feature. If the actual defect resolution is coarser than the finest feature, then the method may proceed to updating the optical properties. If the actual defect resolution is the finest feature, then the method may skip the step of updating the optical properties and may proceed to repair the defect.

In a step 270, the controller 118 may set the optical properties of the laser light 109 based on the defect identified. The optical properties of the laser light 109 may be set based on the defect identified if needed. In embodiments, the controller 118 may check whether the defect is the finest feature. If the actual defect resolution is not the finest feature, then the controller 118 may change the optical properties to match the size of the actual defect resolution. If the defect is the finest feature, then the controller 118 may not change the optical properties because the controller 118 has previously preset the optical properties according to the finest feature. The optical properties may be set based on each defect.

In a step 280, the laser light 109 may repair the defect. The laser light 109 may repair the defect at the defect location by ablating the defect to remove the excess material. The repair system 100 may ablate the defect by removing one or more layers of the excess material until the laser light 109 has removed the excess material defect up to a substrate of the sample, as determined from the image data 117. Adjusting the optical properties based on the defect identified may ensure that each defect is repaired in the shortest time possible, while meeting required repair quality. Setting the optical properties based on each defect may enable repair of all defects on the sample 115 can be performed successfully. Coarser defects on the sample 115 may be repaired optimally, with respect to time. Finer defects on the sample 115 may be repaired optimally, with respect to accuracy. After repair is completed, the optical properties set in step 230 may optionally be reset to match the finest feature before reaching the location of the next defect. Resetting the optical properties to match the finest feature may save time as defects are most likely to be associated with the finest features.

In embodiments, the repair system 100 may iteratively reach the defect location, acquire the image data at the defect location, identify the defect, set the optical properties based on the defect identified, and repair the defect for each known defect (e.g., each defect in a defect report).

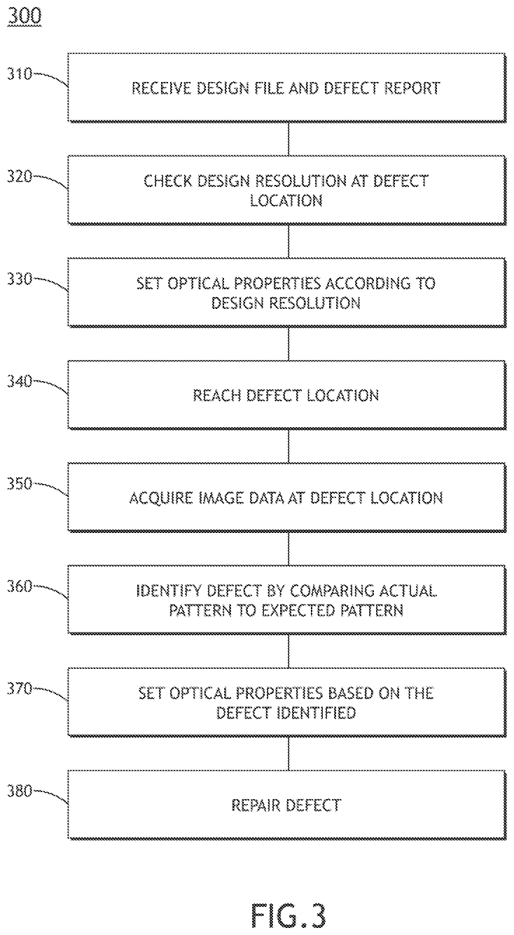

Referring now to FIG. 3, a method 300 is described, in accordance with one or more embodiments of the present disclosure. The method 300 is a method of setting repair properties according to defect resolution. The embodiments and the enabling technologies described previously herein in the context of the repair system 100 should be interpreted to extend to the method. It is further noted, however, that the method is not limited to the architecture of the repair system 100.

In a step 310, the controller 118 may receive a design file of the sample 115. The design file may be a panel design. The controller 118 may also receive a defect report of the sample. The controller 118 may receive the defect report of the sample 115 from an AOI system, or the like. The defect report may include a location of defects on the sample.

In a step 320, the controller 118 may check the design resolution in the design file at the defect location. For example, the design resolution may refer to a line width of a conductor and/or a line spacing between adjacent conductors at the defect location.

In a step 330, the controller 118 may set the optical properties of laser light 109 according to the design resolution in the design file at the defect location. In embodiments, the controller 118 may set the optical properties of the laser light 109 as the sample stage 114 positions the sample 115 such that the defect location in the defect report is within a field-of-view of the detector 116. In this regard, the optical properties may be preset by anticipating the defect size based on the design resolution at the known defect location. The optical properties can be adjusted for each defect according to the location in the design. The optical properties can be changed even before the image data 117 is acquired. The controller 118 may preset the one or more optical properties before the detector 116 generates the image data 117. Changing the optical properties before the image data 117 is acquired may shorten the repair time. Presetting the optical properties according to the expected defect resolution may be beneficial to save time during the repair process. For example, the time spent reaching the defect location may also be spent setting the optical properties. Thus, the repair system 100 may be preset upon reaching the defect location without needing to adjust the optical properties to match the actual defect resolution.

In a step 340, the repair system 100 may reach the defect location on the sample 115. The repair system 100 may reach the defect location by the sample stage 114 positioning the sample 115 such that the defect of the sample is within the field-of-view of the detector 116. The location of the defect is known from the defect report.

In a step 350, the detector 116 may acquire the image data 117 at the defect location. The image data may include a panel image, or the like.

In a step 360, the controller 118 may identify the defect by comparing the actual pattern at the defect location in the image data 117 to the expected pattern at the defect location in the design file. For example, the controller 118 may identify a size of the defect or the like.

After acquiring the image, the repair system 100 may verify that the expected defect resolution matches the actual defect resolution and then does not need to make additional changes to the optical properties.

In a step 370, the controller 118 may set the optical properties of the laser light 109 based on the defect identified. The controller 118 may change the optical properties to match the reference design associated with the defect identified and/or a size of the defect identified. If the defect is the size of the expected feature, then the controller 118 may not need to change the optical properties to match the size of the defect identified where the controller 118 has previously set the optical properties according to the expected size. If the actual defect resolution is different than the expected defect resolution, then the method may proceed to updating the optical properties. If the actual defect resolution is the expected defect resolution, then the method may skip the step of updating the optical properties and proceeds to repair the defect.

In a step 380, the laser light 109 may repair the defect. The laser light 109 may repair the defect at the defect location by ablating the defect to remove the excess material. Adjusting the optical properties based on the defect identified may ensure that each defect is repaired in the shortest time possible, while meeting required repair quality.

In embodiments, the repair system 100 may iteratively check the design resolution in the design file at the defect location, preset the optical properties of the laser light 109 according to the design resolution in the design file at the defect location, reach the defect location, acquire the image data at the defect location, identify the defect in the image data, set the optical properties based on the defect identified, and repair the defect for each known defect (e.g., each defect in a defect report).

In embodiments, the step 320 of checking the design resolution at the defect location may be parallelized with one or more of the steps of the method 300. For example, a design resolution at a current defect may be found. The repair system 100 may then perform one or more repair actions for the current defect (e.g., reach the current defect location, acquire image of the current defect, identify the current defect, set optical properties if needed, and repair the current defect) in parallel with determining optical properties for a subsequent defect. Checking the design resolution in parallel with the other steps may be advantageous to reduce an analysis time of the method. For example, if the resolution analysis and the repair each take a same amount of time, then for all defects save the first one, the analysis time may be spent in parallel to repair of the predecessor defect and the design resolution of the next defect will already be known prior to navigating to the next defect. As another example, if the resolution analysis time is much shorter than the repair time, then the analysis of design resolution of multiple defect locations can take place while repair system 100 performs the first repair. Additional defects can then be sequenced according to their design resolution, minimizing the need to change optical properties between defects.

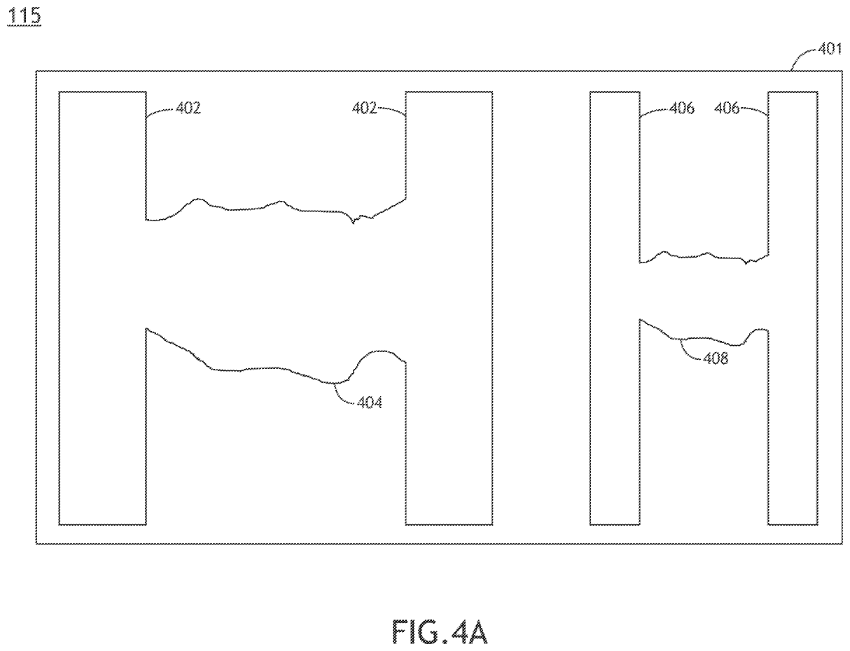

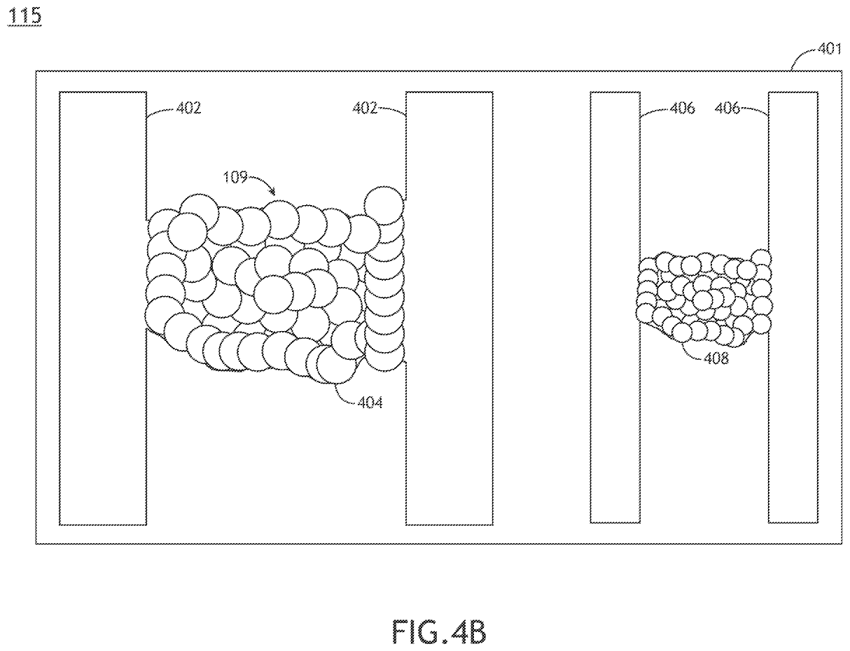

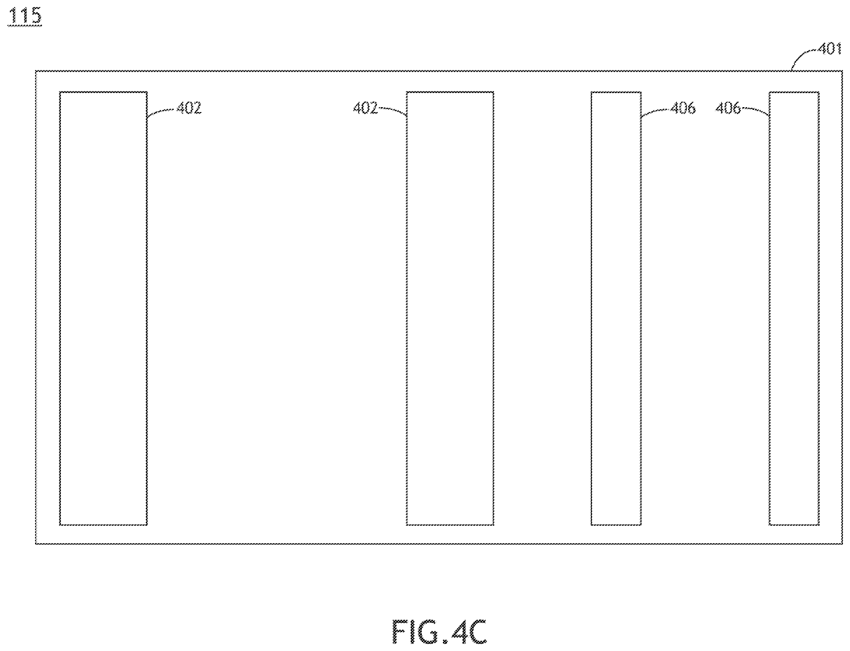

Referring now to FIGS. 4A-4C, the sample 115 is described, in accordance with one or more embodiments of the present disclosure. The sample 115 may include a pair of conductors 402, pair of conductors 406, excess material defect 404, and excess material defect 408. Each of the pair of conductors 402, pair of conductors 406, excess material defect 404, and excess material defect 408 may be disposed on a substrate 401 of the sample 115.

The pair of conductors 402 may include a selected line width and a selected space width. The line width may refer to a width of the pair of conductors 402. The space width may refer to a width of space between the pair of conductors 402. The pair of conductors 402 may include a selected line width and a selected space width which are greater than a line width and a space width of the pair of conductors 406. The pair of conductors 402 may have a resolution which is coarser than the pair of conductors 406.

The excess material defect 404 may be disposed between the pair of conductors 402. The excess material defect 408 may be disposed between the pair of conductors 406. The excess material defect 404 and the excess material defect 408 may also be a short. The conductors and the excess material defect are formed of a conductive material, such as copper, or the like.

The repair system 100 may generate the laser light 109 and direct the laser light 109 to the defects. For example, the repair system 100 may generate the laser light 109 in a plurality of pulses (depicted as circles). The laser light 109 may ablate the excess material defect 404 thereby repairing the pair of conductors 402. The laser light 109 may ablate the excess material defect 408 thereby repairing the pair of conductors 406.

In embodiments, the repair system 100 may change the spot size of the laser light 109. The repair system 100 may change the spot size of the laser light 109 when ablating the excess material defect 404 and ablating the excess material defect 408. The repair system 100 may change the spot size of the laser light 109 based on the line width of the conductors and/or the space width between them. For example, the excess material defect 404 may be a coarse defect and the excess material defect 408 may be a fine defect. The repair system 100 may cause the spot size of the laser light 109 to be smaller when ablating the excess material defect 408 and to be larger when ablating the excess material defect 404. The repair system 100 may change the spot size of the laser light 109 using the method 200 and/or the method 300. In embodiments, the repair system 100 may change between spot sizes by changing at least one of the objective lens 112 or the magnification thereof, a waist position, an iris diameter, or the like. The repair system 100 may find the space width between the conductors and/or the line width of the conductors based on the design file and/or the image data 117.

The throughput of the repair system 100 may be optimized to defect and pattern dimensions by setting the laser spot size according to conductor characteristics, for example pitch and width. Using a fine laser spot for fine conductors and a coarse laser spot for coarse conductors may increase throughput for coarse conductors' repair, while maintaining quality for fine defect repair. If the spot size was set based on the finest feature, then the defect repair of the coarse pitch may take significantly longer. The spot size may be set according to panel characteristics, defect dimensions, or both.

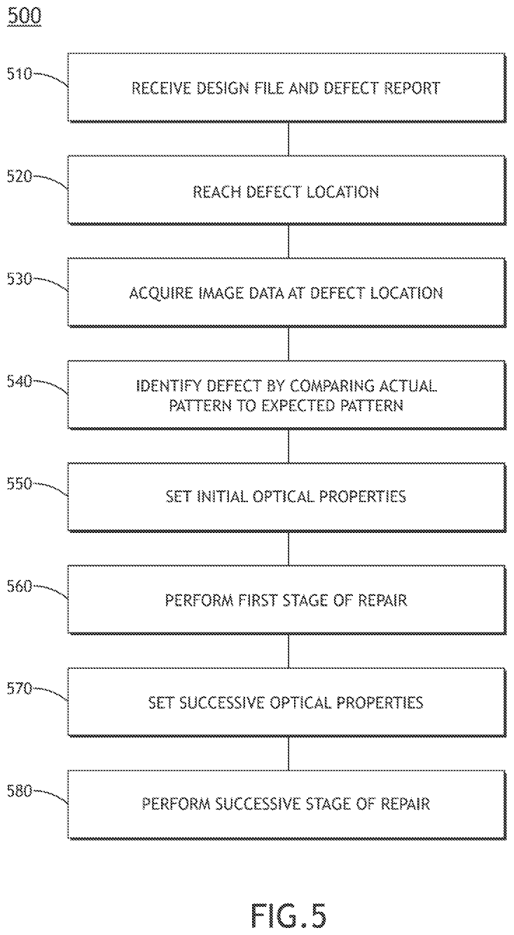

Referring now to FIG. 5, a method 500 is described, in accordance with one or more embodiments of the present disclosure. The method 500 is a method of changing optical properties during repair. The embodiments and the enabling technologies described previously herein in the context of the repair system 100 should be interpreted to extend to the method. It is further noted, however, that the method is not limited to the architecture of the repair system 100.

In a step 510, the controller 118 may receive a design file of the sample 115. The design file may be a panel design. The controller 118 may also receive a defect report of the sample. The controller 118 may receive the defect report of the sample 115 from an AOI system, or the like. The defect report may include a location of defects on the sample.

In a step 520, the repair system 100 may reach the defect location on the sample 115. The repair system 100 may reach the defect location by the sample stage 114 positioning the sample 115 such that the defect of the sample is within the field-of-view of the detector 116. The location of the defect may be known from the defect report.

In a step 530, the detector 116 may acquire the image data 117 at the defect location. The image data may include a panel image, or the like.

In a step 540, the controller 118 may identify the defect by comparing the actual pattern at the defect location in the image data 117 to the expected pattern at the defect location in the design file. For example, the controller 118 may identify a size of the defect or the like.

In a step 550, the controller 118 may set the optical properties of the laser light 109. The optical properties of the laser light 109 may be set according to the defect identified in the image data.

In a step 560, the repair system 100 may perform a first stage of defect repair. The first stage of defect repair may include multiple scans of the laser light 109 directed at the defect. The repair system 100 may focus the laser light 109 at the defect to perform multiple layers of scans of the laser light 109 starting from a height and working towards the substrate. The scans of the laser light 109 may also be referred to as ablation actions. The scans may be performed one on top of another. Each scan may remove a layer of material. The layer may include a certain volume or certain depth of the excess material. The repair system 100 may remove the layer of the excess material defect 404 with each scan. In embodiments, the repair system 100 may perform several repeated ablations between focus adjustments. Performing the repeated ablations between focus adjustments may be desirable to reduce the number of refocusing actions, thereby saving time and/or accuracy. Thus, the laser light 109 may be refocused as needed. In embodiments, the repair system 100 may refocus the laser light 109 on the next layer of the excess material. The repair system 100 may refocus the laser light 109 when the aggregate removed depth from last focus position is on the order of the Rayleigh length of laser light 109. For example, if the Rayleigh length is 2 um and each ablation removes 0.5 um of material, then repair system 100 may refocus the laser light 109 every 4 ablations.

In embodiments, the repair system 100 may focus the laser light 109 at the excess material defects 404 at a height of the top of the conductors 402. For example, the laser light 109 may be focused at the height of the top of the conductors 402 where 3D information of the defect is not known to the repair system 100. The repair system 100 may focus the laser light 109 to perform multiple layers of scans of the laser light 109 starting from the top of the conductors 402 and working towards the substrate 401.

In embodiments, repair system 100 may focus the laser light 109 at the excess material at a height of the top of the excess material defect 404. The repair system 100 may know the top of the excess material defect 404 from a focus measure of the defect surface, 3D profile data, or the like. For example, the height of the defect may be inferred from the focus measure, where a lower focus measure may mean the defect surface is further from the conductors 402 and a higher focus measure may mean the defect surface is closer to the conductors 402. 3D imagery may be used to determine the 3D profile data of the excess material defect 404. The repair system 100 may focus the laser light 109 to perform multiple layers of scans of the laser light 109 starting from the top of the excess material defect 404 and working towards the substrate 401.

The repair system 100 may acquire the image data 117. The image data 117 may be acquired before any ablation actions are carried out. The image data 117 may also be acquired after one or more of the layers of laser scans. The controller 118 may use the image data 117 to determine the laser is nearing the substrate, indicating to stop the first stage of defect repair. Additional of the image data 117 may be acquired as the ablation is closer to the substrate 401. For example, the controller 118 may determine that the defect has been repaired by detecting that the defect is no longer present at the defect location in the image data 117 (e.g., from a fluorescence image). Although the repair system 100 is described as taking the image after one or more of the layers of laser scans, this is not intended as a limitation of the present disclosure. In embodiments, the repair system 100 may perform the first stage and set the successive optical system properties without taking an additional image. For example, the repair system 100 may perform the first stage and set the successive optical system properties if the resolution of the initial image is sufficiently high.

In a step 570, the controller 118 may change the optical properties of the laser light 109. In embodiments, the optical properties may be changed to a finer pitch to complete the second stage of repair. It is further contemplated that the optical properties may include changing an energy, waist position (e.g., focus position), scan speed, inter-line shift, and the like.

In a step 580, the repair system 100 may perform the second stage of repair. The second stage of defect repair may include multiple scans of the laser light 109 directed at the defect. The repair system 100 may focus the laser light 109 at the remaining portion of the excess material defect 404.

The repair system 100 may change the optical properties as the repair progresses in order to combine both accuracy and speed. For example, the repair system 100 may achieve high accuracy for fine resolution defects and higher speed for coarse resolution defects. In embodiments, the repair system 100 may start with a large laser spot and do one or several iterations to initially remove part of the excess material. The repair system 100 may then change the optical properties of the laser light 109 to a smaller spot size and do one or several iterations to remove the fine residue of the defect.

Although the method is described with a second stage of repair, it is contemplated that the method may include n-number of stages, where n is an integer of two or greater. The optical properties may be changed for each of the stages.

In embodiments, the repair system 100 may iteratively reach the defect location on the sample 115, acquire the image data 117 at the defect location, identify the defect, set the optical properties of the laser light 109, perform the first stage of defect repair, change the optical properties of the laser light 109, and perform the second stage of repair for each known defect in the defect report.

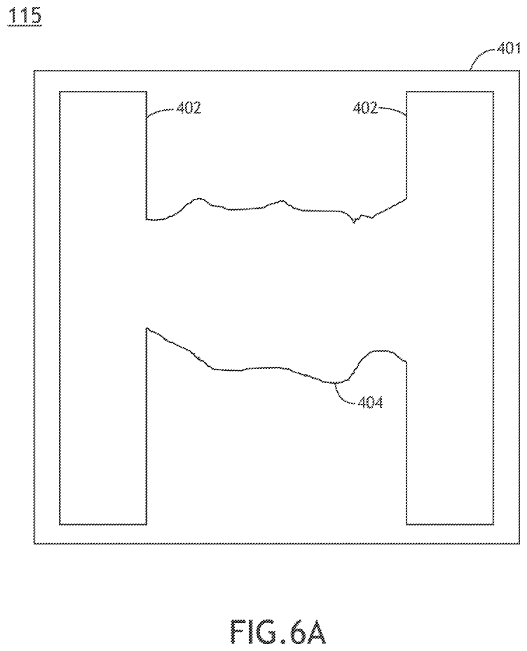

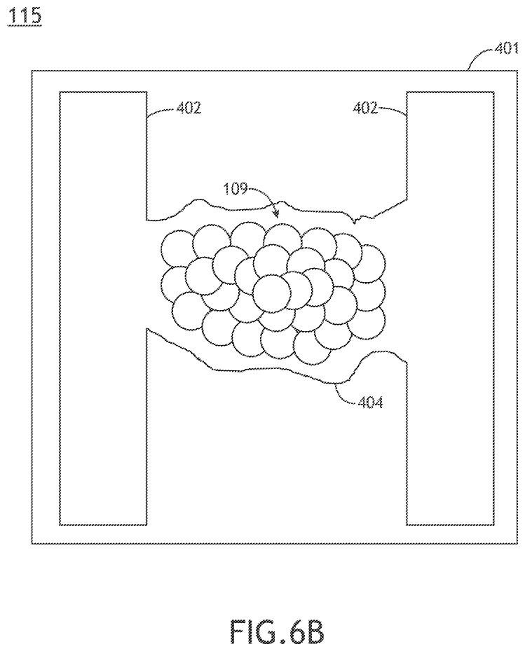

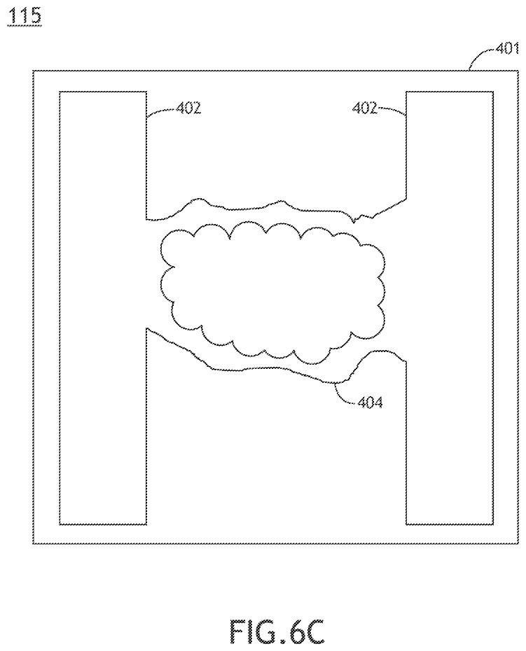

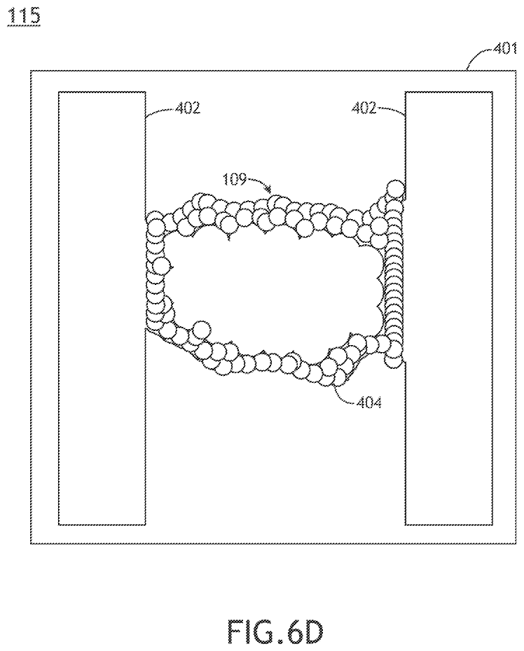

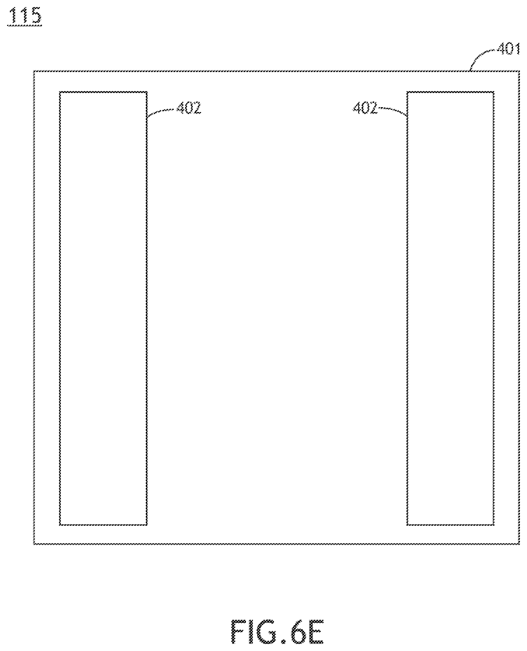

Referring now to FIGS. 6A-6E, the sample 115 is described, in accordance with one or more embodiments of the present disclosure. In embodiments, the repair system 100 may set the spot size of the laser light 109 to a first spot size, energy, fluence, and the like. The first spot size may be a crude spot size that ablates larger areas of the excess material defect 404. The repair system 100 may perform a first stage repair of the excess material defect 404 using the first spot size, energy, fluence, and the like for the laser light 109. In the first stage of repair, a large laser spot may be used in all defect portions where high accuracy is not required. The first stage may be a fast, less accurate stage which may be performed very quickly owing to the large spot size and/or other parameters, for example high pulse energy and high fluence.

The repair system 100 may scan the laser light 109 along one or more portions of the defects. The repair system 100 may scan the laser light 109 along a center of the defects, an entire defect area except areas close to the conductors 402, an entire defect area except areas close to the substrate 401, and the like. The areas close to the conductors 402 may be considered a defect-conductor interface. The areas close to the substrate 401 may be considered a defect-substrate interface. In embodiments, the repair system 100 may scan the laser light 109 along the center of the excess material defect 404. The repair system 100 may scan the laser light 109 along the center of the excess material defect 404. The center of the excess material defect 404 may be removed during the first stage of repair, with portions where high accuracy is required remaining after removal. The repair system 100 may scan the laser light 109 along the center of the excess material defect 404 and may not scan the laser light 109 along the exterior perimeter of the excess material defect 404 in the first stage. The exterior perimeter of the excess material defect 404 may be the interface between the excess material defect 404 that may need to be removed and the substrate. The substrate should not be damaged. The exterior perimeter of the excess material defect 404 may not be scanned during the first stage because the exterior perimeter of the excess material defect 404 may be difficult to scan using the first spot size, first pulse energy, and first fluence without damaging the substrate. For example, if the laser light 109 with the first spot size, first pulse energy, and first fluence partially hits the substrate and partially hits the excess material defect 404, the laser light 109 may excessively damage the substrate.

The repair system 100 may change the spot size, pulse energy, fluence, and the like of the laser light 109 during repair of the excess material defect 404. For example, the repair system 100 may change the spot size of the laser light 109 while also reducing the energy, thereby not changing the fluence. The repair system 100 may change the spot size of the laser light 109 to a second spot size. The second spot size may be smaller than the first spot size. Thus, the repair system 100 may reduce the spot size once the center is ablated. The repair system 100 may perform a second stage repair of the excess material defect 404 using the second spot size for the laser light 109. The repair system 100 may scan the laser light 109 along the exterior perimeter of the excess material defect 404. The second stage may be very accurate but slow. Due to the small spot size, energy can be reduced to avoid excessive laser fluence. The excessive laser fluence may undesirably cause large substrate damage. The smaller spot size may have a reduced chance of hitting the substrate, thereby reducing damage to the substrate.

The second stage of repair may commence after the first stage has been completed. The first stage of repair may be completed upon one or more conditions. The conditions may include open loop conditions, closed loop conditions, and the like. For example, the open loop conditions may include performing a set number of ablation actions. By way of another example, the closed loop conditions may include a sharpness of the defect in the image data. For instance, the controller 118 may determine that the sharpness of the defect in image data 117 is sufficiently reduced, indicating that the defect surface is far from image focus (and therefore close to position of substrate 401). By way of another example, the closed loop conditions may include feedback from a 3D measurement. The 3D measurement may show that the defect has been ablated to a set distance from the substrate 401.

Changing the spot size during the repair may combine speed when removing the center with accuracy when removing the exterior perimeter. Using a single spot size may be unable to achieve both speed and accuracy. If only the large spot size is used, the laser may damage the substrate. If only the small spot size is used, the speed when removing the center is slower.

Although the second spot size has been described as smaller than the first spot size, this is not intended as a limitation of the present disclosure. It is contemplated that the second spot size may be larger than the first spot size. For example, a highly accurate repair may employ a small spot size which is concluded by a delicate laser cleaning stage which will remove fine debris from a large area, using a larger spot size.

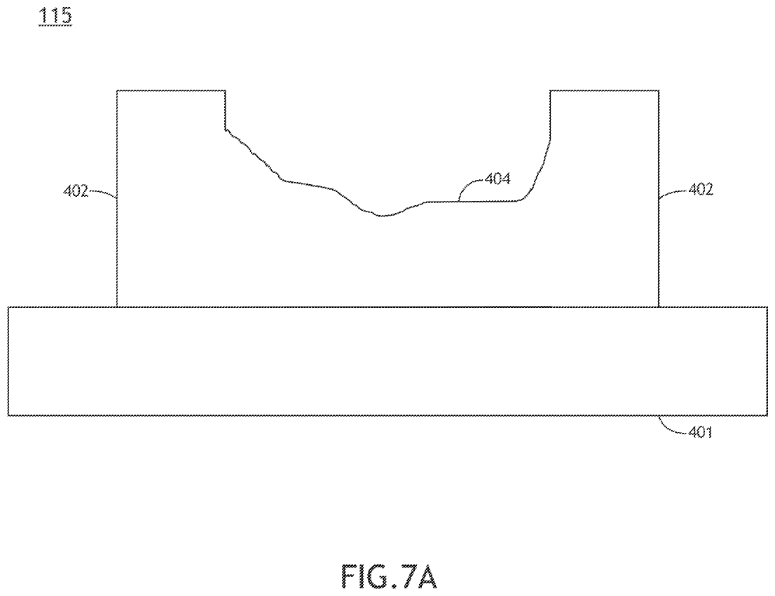

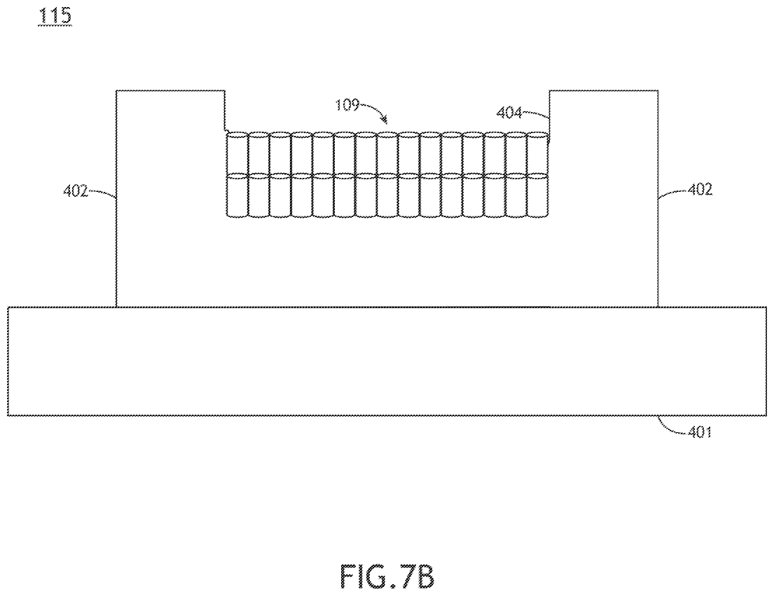

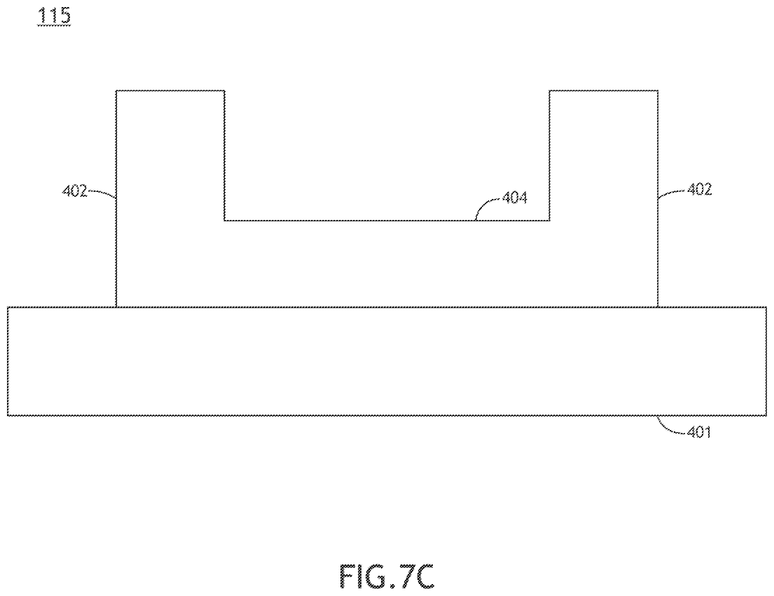

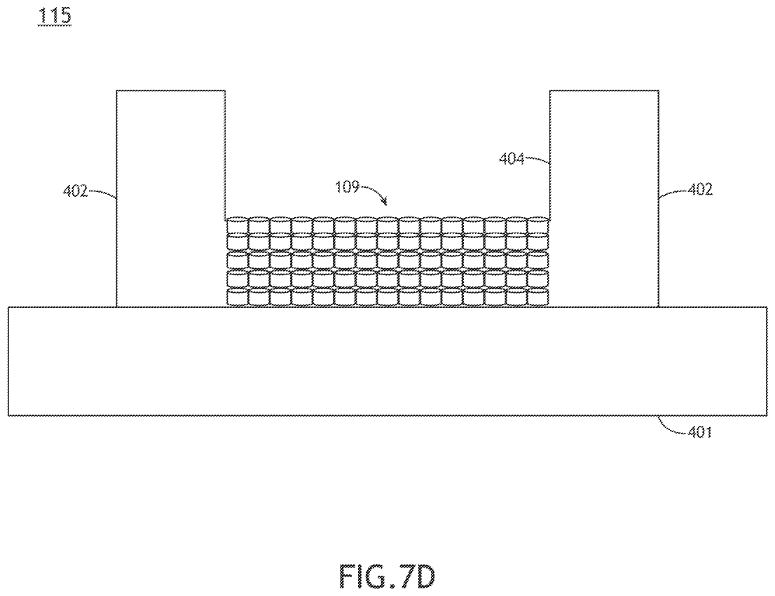

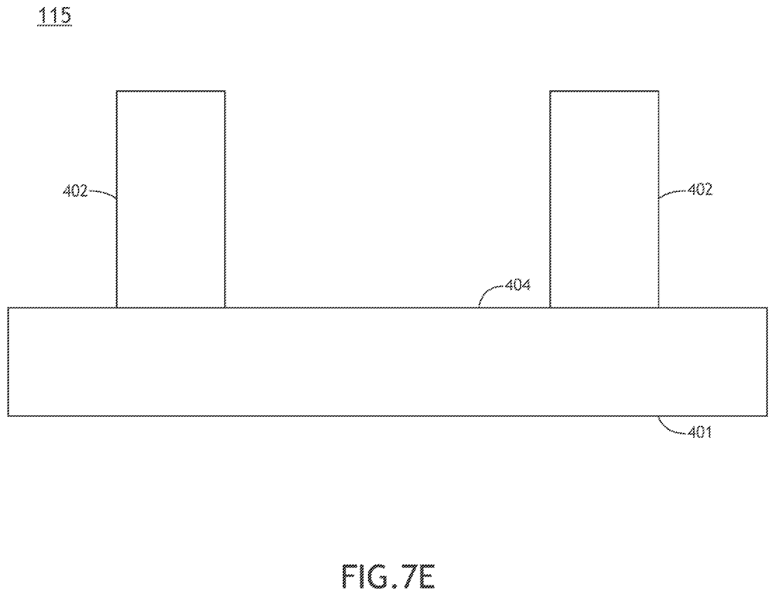

Referring now to FIGS. 7A-7E, the sample 115 is described, in accordance with one or more embodiments of the present disclosure. In embodiments, the repair system 100 may change a fluence of the laser light 109 during repair of the sample 115. The repair system 100 may change the fluence of the laser light 109 by changing the energy, changing a laser beam expander magnification, changing a focus plane of the laser spot (fluence change by defocus), and the like. In embodiments, the repair system 100 may change the fluence while maintaining the spot size. The repair system 100 may change the fluence while maintaining the spot size by changing the energy of the laser light 109.

The repair system 100 may perform a first stage of repair using a first fluence. For example, the first stage of repair may be performed at high fluence. Each pulse of the laser light 109 at the high fluence may remove a large thickness of the excess material defect 404. The first stage may include iterative pulses at smaller and smaller distances towards the substrate 401. The repair system 100 may stop the first stage of repair once the laser light 109 is proximate to the substrate 401. If the repair had continued using the first fluence, then the laser light 109 may undesirably damage the substrate 401. For instance, the laser light 109 may ablate a thickness of the substrate which may be relatively large (e.g., on the order of one micrometer or more). The repair system 100 may perform one or more scans at the first fluence. The repair system 100 may repeat the scanning and refocusing until the laser light 109 approaches the substrate 401.

The repair system 100 may perform a second stage of repair following the first stage of repair. The second stage repair may be performed once a portion of defect thickness has been ablated in the first stage of repair. The controller 118 may determine the portion of the defect thickness has been ablated using one or more open loop and/or closed loop conditions. For example, the controller 118 may estimate the thickness ablated during each ablation action in the first stage of repair using the fluence as an open loop condition. By way of another example, the controller 118 may determine the thickness in the first stage of repair using the image data 117 and/or a 3D measurement as a closed loop condition. The repair system 100 may perform the second stage of repair using a second fluence. The second fluence is lower than the first fluence. Each pulse of the laser light 109 at the second fluence may remove a smaller thickness of the excess material defect 404 than the thickness removed at the first fluence. Using the second fluence may result in reduced damage to the substrate 401. The repair system 100 may perform one or more scans at the second fluence. Thus, as the excess material is ablated by the application of the laser light 109, the fluence of the laser light 109 may be reduced to minimize damage to the substrate 401.

In embodiments, the repair system 100 may select the fluence of the laser light 109 based on the ablation depth at the fluence. For a given fluence, the laser light 109 may ablate a first depth of material. The fluence may be selected to remove the first depth of material in each scan. The repair system 100 may direct each pulse of the laser light 109 to the defect while focused at a first height. The pattern of the pulses can be performed sequentially or non-sequentially in space. For example, the pattern of the pulses may be scanned sequentially. By way of another example, the pattern of the pulses may be directed non-sequentially by using acousto-optic deflectors which direct each pulse to different coordinates in a non-serial fashion. As used herein, scanning may refer to directing the pulses either sequentially or non-sequentially.

The repair system 100 may refocus the optics at the first depth below the first height and repeat directing the pulses of the laser light 109. The repair system 100 may repeat directing the pulses of the laser light 190 and refocusing, when needed, until reaching a given height above the substrate. The repair system 100 may then adjust the fluence to remove a second depth of material in each layer. The second depth of material may be less than the first depth of material. The repair system 100 may perform the second stage scans at the given height, optionally refocusing the optics at the second depth below the given height, and may then repeat the scanning and refocusing. Refocusing the optics may or may not be performed for every ablation. The repair system 100 may repeat the scanning and refocusing until reaching the substrate.

For example, given the depth of the excess material is 4 micrometers, the first fluence may be selected to ablate 1 micrometer. The laser light 109 may be scanned starting at a height of 4 micrometers using the first fluence ablating 1 micrometer. The laser light 109 may then be refocused at the height of 3 micrometers from the substrate 401 using the first fluence ablating 1 micrometer. For this example, each scan may remove one micrometer. The repair system 100 may stop scanning the laser once the laser has ablated the defect down to a given height of 2 micrometers from the substrate 401. The repair system 100 may then select a second fluence which is expected to remove a smaller depth of material. For instance, the second fluence may be selected to ablate one-quarter micrometer thickness. The laser light 109 may be scanned at heights starting from the 2-micrometer height away from the substrate 401 using the second fluence. The repair system 100 may then remove several one-quarter micrometer thick layers until the laser light 109 has removed the excess material defect 404 up to the substrate 401. For example, the controller 118 may determine that the defect has been repaired by detecting that the defect is no longer present at the defect location in the image data 117 (e.g., from a fluorescence image).

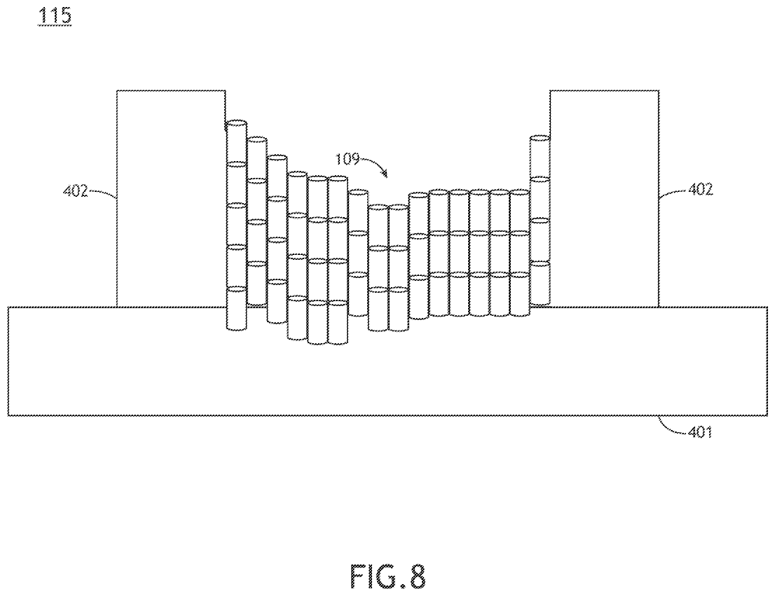

Referring now to FIG. 8, the sample 115 is described, in accordance with one or more embodiments of the present disclosure. In embodiments, the repair system 100 may change a waist position of the laser light 109 during repair of the sample 115. The repair system 100 may change the waist position of the laser light 109 by changing a focus of the objective lens 112, moving the objective lens 112, moving the sample 115, and the like.

The repair system 100 may know a height profile of the excess material defect 404. For example, the repair system 100 may know the height profile of the excess material defect 404 from a 3D measurement. By way of another example, the repair system 100 may know the height profile of the excess material defect 404 from a heuristic estimating height from texture sharpness in the image data 117.

In embodiments, the repair system 100 may control the waist position of the laser light 109 as the laser light 109 is scanned along the excess material defect 404. For example, the controller 118 may direct the waist position causing the laser light 109 to follow the height profile of the excess material defect 404. The repair system 100 may focus the waist position of the laser light 109 to follow along the height profile. Each of the pulses of the laser light 109 may follow along the height profile. Focusing the waist position of the laser light 109 along the height profile may reduce the number of pulses required for repair, resulting in a shorter repair time.

Controlling the waist position as the laser beam is scanned to follow the 3D profile may be desirable to reduce the number of scans performed by the repair system 100, and similarly reduce the repair time. Tracking the defect profile while the laser is scanning may result in higher ablation efficiency. The higher ablation efficiency may result in higher throughput and a more accurate repair. Defects are typically not of uniform thickness, so that focusing on the tallest region of the defect would be in the air at other, lower regions of the defects. When the laser focus is in air, the laser light 109 may defocus and may illuminate a larger area on the defect and/or cause the laser light 109 to hit the reference conductor or the substrate. Thus, repair system 100 may achieve a speed advantage as well as a quality advantage by following the 3D profile and not focusing the waist position of the laser light 109 on the air above the excess material defect 404.

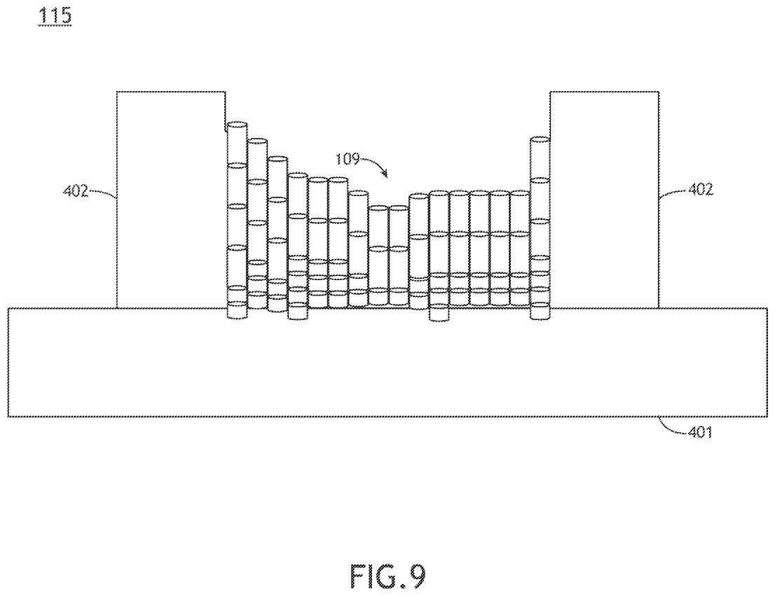

Referring now to FIG. 9, the sample 115 is described, in accordance with one or more embodiments of the present disclosure. In embodiments, the repair system 100 may change the waist position and the fluence of the laser light 109 during repair of the sample 115. The repair system 100 may perform a repair using a variable focus and variable fluence. The repair may be performed where the focus and fluence are controlled. A higher fluence may be used at coordinates where the defect is thicker, and a lower fluence may be used where the defect is thinner. In embodiments, the focus and fluence may be controlled in stages. In embodiments, the focus and fluence may be controlled per-pulse.

In embodiments, the repair system 100 may control the waist position of the laser light 109 as the laser light 109 is scanned along the defect. For example, the repair system 100 may control the focus causing the waist position of the laser light 109 to follow the 3D profile of the excess material defect 404. The repair system 100 may focus the waist position of the laser light 109 along the height profile. Each of the pulses of the laser light 109 may follow along the height profile. Focusing the waist position of the laser light 109 along the height profile may reduce the number of pulses required for repair, resulting in shorter repair time.

The repair system 100 may additionally control the fluence and the waist position of the laser light 109 as the laser light 109 is scanned along the defect. The repair system 100 may perform a first stage of repair using a first fluence. For example, the first stage of repair may be performed at high fluence. Each pulse of the laser light 109 at the high fluence may remove a large portion of the excess material defect 404. The pulses of the laser light 109 penetrate to a further depth using larger fluences. The first stage may include iterative pulses at lower and lower distances towards the substrate 401. The repair system 100 may stop once the laser light 109 is proximate to the substrate 401. If the repair had continued using the first fluence, then the laser light 109 may undesirably penetrate and damage the substrate 401. For instance, the penetration of the laser light 109 into the substrate may be relatively large (e.g., on the order of one-half micron or more). The repair system 100 may perform one or more scans at the first fluence. The repair system 100 may repeat the scanning and refocusing until the laser light 109 approaches the substrate 401.

When the laser light 109 approaches the substrate 401, the repair system 100 may stop and reduce the fluence. The controller 118 may use the image data 117 and/or 3D measurement data as feedback to determine when to stop and reduce the fluence. The fluence may be reduced so that the laser light 109 does not penetrate the substrate 401. As the excess material is ablated by the application of the laser light 109, the fluence of the laser light 109 may be reduced to avoid damage to the substrate 401.

The repair system 100 may perform a second stage of repair following the first stage of repair. The second stage repair may be performed once all defect regions have been sufficiently ablated in the first stage of repair such that all remaining matter is proximate to the substrate. The repair system 100 may perform the second stage of repair using a second fluence. The second fluence may be lower than the first fluence. Each pulse of the laser light 109 at the second fluence may remove a smaller thickness of the excess material defect 404. Using the second fluence may result in reduced damage to the substrate 401. The repair system 100 may perform one or more scans at the second fluence.

In embodiments, the repair system 100 may perform the first and second stage of repair per position on a pulse-by-pulse basis. The stage of repair may correspond to the point being repaired in the defect. For example, the repair system 100 may perform the first stage repair using the first fluence and second stage at the second fluence for thicker defects. By way of another example, the repair system 100 may proceed directly to the second stage without performing the first stage for thinner defects. Thus, the first and second stage of repair may be performed per position on a pulse-by-pulse basis according to the thickness of the defect.

The total number of pulses required to remove the excess material may be reduced by controlling the waist position and fluence of the laser light 109 as the laser light 109 is scanned along the defect, as compared to the only controlling the fluence of the laser light 109 as the laser light 109 is scanned along the defect. Reducing the number of pulses may shorten the repair time. Additionally, penetration of the substrate by the laser light 109 may be reduced by controlling the waist position and fluence of the laser light 109 as the laser light 109 is scanned along the defect, as compared to the only controlling the focus of the laser light 109 as the laser light 109 is scanned along the defect.

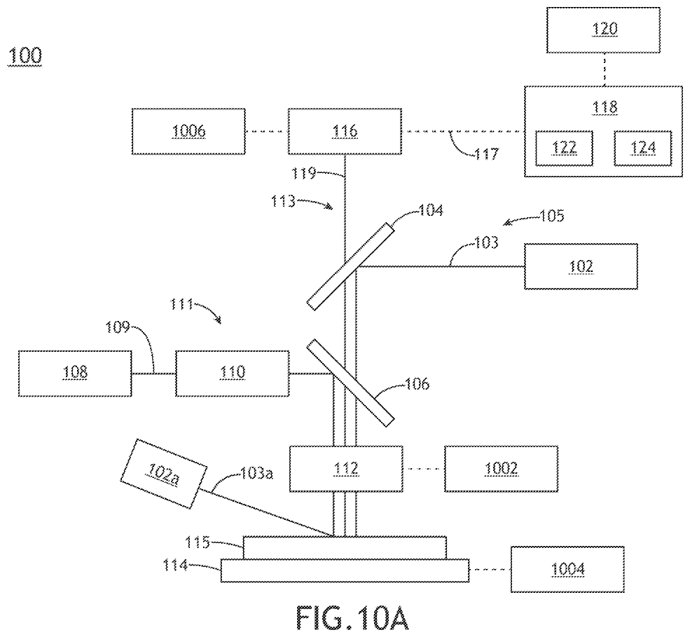

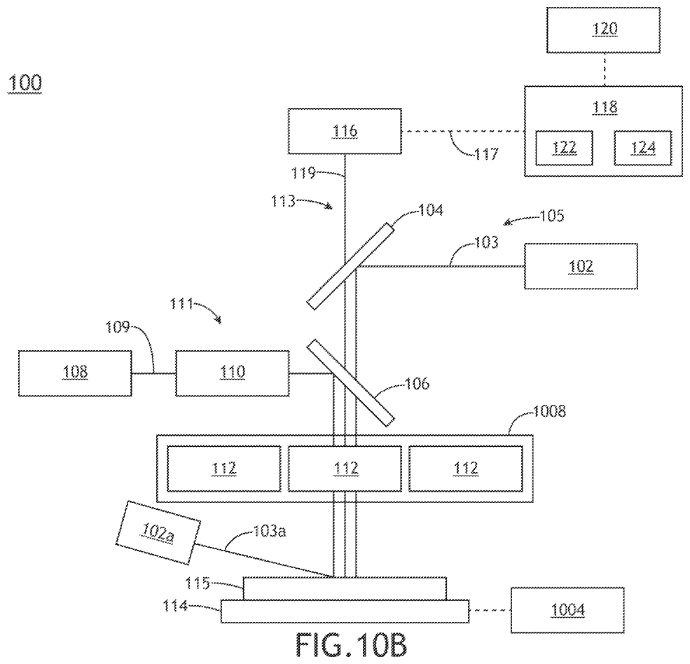

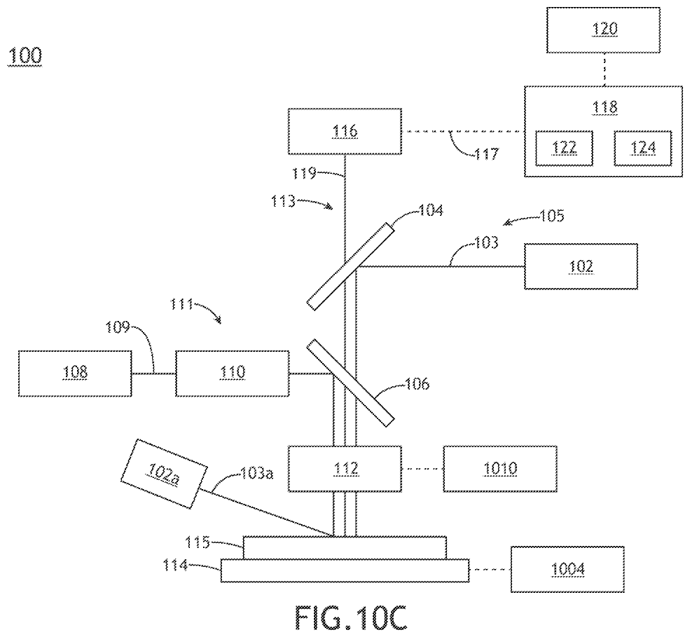

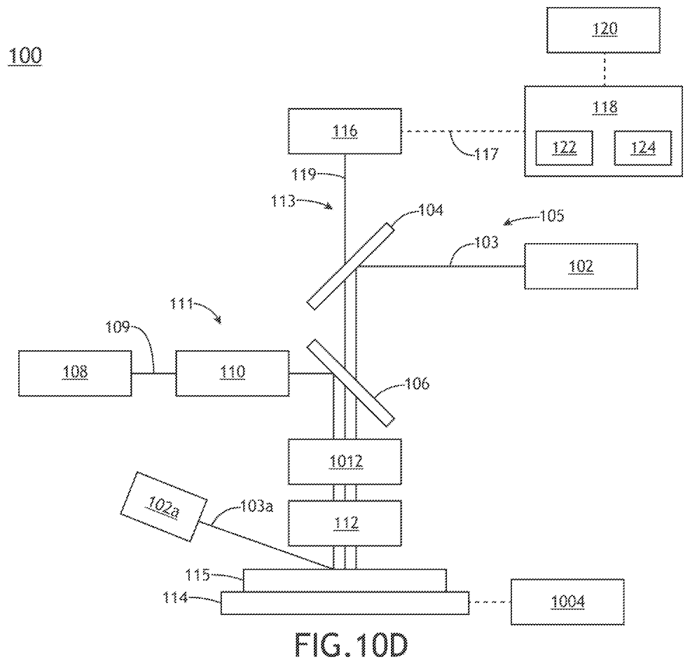

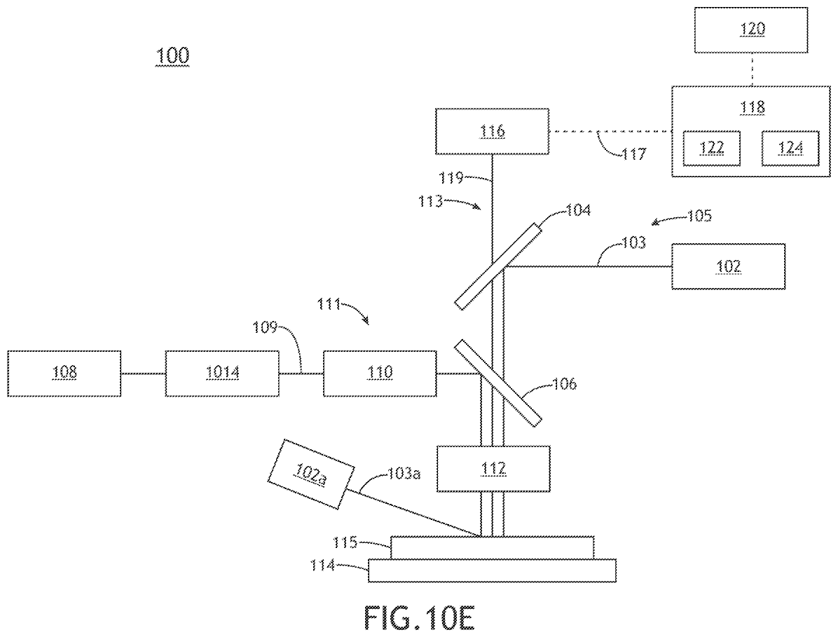

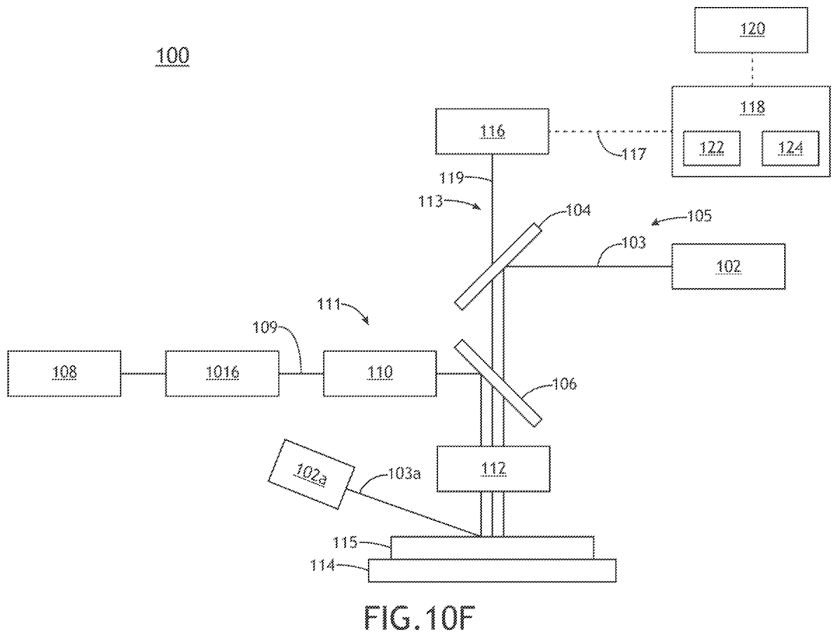

Referring now to FIGS. 10A-10F, the repair system 100 is described, in accordance with one or more embodiments of the present disclosure. The repair system 100 may include one or more additional components to change the optical properties of the laser light 109. For example, the repair system 100 may include a z-axis positioner 1002, z-axis positioner 1004, z-axis positioner 1006, objective lens turret 1008, zoom motor 1010, iris 1012, variable beam expander 1014, diffractive optical element 1016, and the like.

In embodiments, the repair system 100 may include z-axis positioner 1002. The z-axis positioner 1002 may be coupled to the objective lens 112. The z-axis positioner 1002 may change the position of the objective lens 112 along the z-axis. The controller 118 may cause the z-axis positioner 1002 to change the position of the objective lens 112. The z-axis may be on-axis or orthogonal to the sample 115. For example, the z-axis may refer to a height of the objective lens 112 relative to the sample 115. Changing the position of the objective lens 112 along the z-axis may shift the focal plane of the detector 116 (i.e., the focus of the image data 117) and shift the waist position of the laser light 109 relative to sample 115.

In embodiments, the repair system 100 may include z-axis positioner 1004. The z-axis positioner 1004 may be coupled to the sample stage 114. The z-axis positioner 1004 may change the position of the sample 115 along the z-axis. The controller 118 may cause the z-axis positioner 1004 to change the position of the sample 115. Changing the position of the sample 115 along the z-axis may shift the focal plane of the detector 116 (i.e., the focus of the image data 117) and shift the waist position of the laser light 109 relative to sample 115.

In embodiments, the repair system 100 may include z-axis positioner 1006. The z-axis positioner 1006 may be coupled to the detector 116. The z-axis positioner 1006 may change the position of the detector 116 along the z-axis. The controller 118 may cause the z-axis positioner 1006 to change the position of the detector 116. Changing the position of the detector 116 along the z-axis may shift the focal plane of the detector 116 (i.e., the focus of the image data 117) but may not shift the waist position of the laser light 109. The z-axis positioner 1006 may be used in combination with the z-axis positioner 1002 and/or the z-axis positioner 1004 to maintain the focus of the detector 116 while shifting the waist position of the laser light 109. The z-axis positioner 1006 may be used in combination with the z-axis positioner 1002 and/or the z-axis positioner 1004 to alter the focus of the detector 116 while maintaining the waist position of the laser light 109 on the sample 115.

In embodiments, the repair system 100 may include objective lens turret 1008. The objective lens turret 1008 may include multiple of the objective lenses 112. Each of the objective lenses 112 may include a magnification, numerical aperture, and the like. The objective lens turret 1008 may change between the objective lenses 112. The controller 118 may cause the objective lens turret 1008 to change between the objective lenses 112 through which the illumination 103 and/or the laser light 109 is configured to pass. Changing the objective lens 112 may refer to placing the objective lens 112 in the path of the illumination 103 and/or the laser light 109. For example, the objective lens turret 1008 may rotate between the objective lenses 112. Changing between the objective lenses 112 may change the field-of-view, the image magnification, the numerical aperture, the image pixel size, the Rayleigh length of the laser beam, the spot size, and the like. The repair system 100 may then change between the objective lens 112 to process conductors which have significantly different spacing between adjacent conductors.

In embodiments, the repair system 100 may include zoom motor 1010. The zoom motor 1010 may be coupled to the objective lens 112. The zoom motor 1010 may control a magnification of the objective lens 112. The controller 118 may cause the zoom motor 1010 to control the magnification of the objective lens 112. For example, the objective lens 112 may be a zoom objective lens. Changing the magnification of the objective lens 112 may change the field of view, the image magnification, the numerical aperture, the Rayleigh length, the spot size, and the like.

In embodiments, the repair system 100 may include iris 1012. The iris 1012 may be disposed in the pupil plane of the objective lens 112. The iris 1012 may control the numerical aperture of the objective lens 112. The iris 1012 may be external or internal to the objective lens 112. Where the iris 1012 is internal to the objective lens 112, the objective lens 112 may be a variable aperture objective lens. The controller 118 may cause the iris 1012 to change the aperture of the objective lens 112. For example, the controller 118 may change the aperture of the iris 1012 using a motor or the like. Changing the aperture of the objective lens 112 changes the image intensity, the numerical aperture, the Rayleigh length, the spot size, and the like.

In embodiments, the repair system 100 may include variable beam expander 1014. The variable beam expander 1014 may change the diameter of the laser light 109, and subsequently the laser spot size, the Rayleigh length, and the like. The controller 118 may cause the variable beam expander 1014 to change the diameter of the laser light 109. The variable beam expander 1014 does not impact the focus of the detector 116 and/or the properties of the image data 117.

In embodiments, the laser generator 108 may have a tunable wavelength. For example, the laser generator 108 may be tunable over a range, or can be selected from a set of wavelengths (e.g., 1064 nm, 532 nm, 355 nm, 266 nm). The controller 118 may cause the laser generator 108 to change the wavelength of the laser light 109. Changing the wavelength of the laser light 109 may change the Rayleigh length, the spot size, and the like. Changing the wavelength of the laser light 109 may not impact the focus of the detector 116 and/or the properties of the image data 117. If an optical element having a large dependence on wavelength is used in conjunction with a laser generator 108 having tunable wavelength, then tuning the wavelength may be used to change the waist position of the laser light 109.

In embodiments, the repair system 100 may include diffractive optical element 1016. The controller 118 may control the diffractive optical element 1016. For example, the diffractive optical element 1016 may be inserted or removed from the laser path 111. The diffractive optical element 1016 may include a tunable phase element or the like. The diffractive optical element 1016 may change the beam profile of the laser light 109. The controller 118 may cause the diffractive optical element 1016 to change the beam profile of the laser light 109. Changing the beam profile may improve ablation depth uniformity (e.g., using a top-hat profile) or avoiding damage to the pattern conductors (e.g., using a Gaussian profile). The Gaussian distribution may be desirable for most applications. The diffractive optical element 1016 may change the beam profile of the laser light 109 to a non-Gaussian distribution. For example, the diffractive optical element 1016 may change the beam profile to a flat top spot or a uniform intensity spot. The diffractive optical element 1016 may not impact the focus of the detector 116 and/or the properties of the image data 117.

The repair system 100 may include any combination of the z-axis positioner 1002, the z-axis positioner 1004, the z-axis positioner 1006, the objective lens turret 1008, zoom motor 1010, iris 1012, variable beam expander 1014, and/or diffractive optical element 1016. The controller 118 may control any of the z-axis positioner 1002, the z-axis positioner 1004, the z-axis positioner 1006, the objective lens turret 1008, the zoom motor 1010, the iris 1012, the variable beam expander 1014, and/or the diffractive optical element 1016 to change the optical properties of the illumination 103, laser light 109, and/or collected light 119 based on either open loop conditions, for example a predefined repair stage, or based on closed loop conditions, for example feedback from the image data 117 and/or 3D measurements during the repair of the defects.

Referring generally again to FIGS. 1-10F. In embodiments, the repair system 100 may use multiple of the objective lens. The repair system 100 may include a first objective lens for the illumination 103 and a second objective lens for the laser light 109. The first objective lens may be used for 3D measurement or for image data 117 with a high resolution. For example, the first objective lens may be used when taking a 3D measurement of the defect, or when acquiring image data 117 for accurate defect identification. The first objective lens may include a magnification which is higher than the magnification of the second objective lens. The higher magnification may be undesirable for the repair, because the higher magnification reduces the spot size of the laser below a minimum size. Reducing the spot size of the laser below the minimum size may significantly reduce the speed of the repair and increase the fluence (e.g., depth of penetration). In this regard, a resolution of the collected light 119 may change without changing the spot size of the laser light 109.

Although much of the present disclosure is directed to repairing excess material defects, this is not intended as a limitation of the present disclosure. It is contemplated that the repair system 100 may also repair a missing material defect. The repair system 100 may include material dispensing hardware to repair the missing material defect. The material dispensing hardware may include chemical vapor deposition (CVD) hardware, solid or liquid dispensing hardware, laser-induced forward transfer (LIFT), ink-jet or other-directed material deposition systems. The repair system 100 may perform various repair operations. Repair operations include, for example, ablating spurious portions of conductors, removal of oxides formed on conductor portions, and/or processes to locally deposit additional conductor material or additional substrate material. Additional conductor material may be deposited and then irradiated by the laser light 109 to join the additional conductor material with the printed circuit. Although not depicted, the repair system may also include functionality for depositing a conductor portion at locations where a part of a conductor is missing or malformed, and/or functionality for depositing a substrate portion at locations where a part of a substrate is missing or malformed. For example, the repair system may include an inkjet device.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application-specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program. Moreover, different subsystems of the system may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers.

In embodiments, a controller may include one or more controllers housed in a common housing or within multiple housings. In this way, any controller or combination of controllers may be separately packaged as a module suitable for integration into a system. Further, the controllers may analyze data received from detectors and feed the data to additional components within the system or external to the system.

The memory medium may include any storage medium known in the art suitable for storing program instructions executable by the associated one or more processors. For example, the memory medium may include a non-transitory memory medium. By way of another example, the memory medium may include, but is not limited to, a read-only memory (ROM), a random-access memory (RAM), a magnetic or optical memory device (e.g., disk), a magnetic tape, a solid-state drive and the like. It is further noted that memory medium may be housed in a common controller housing with the one or more processors. In one embodiment, the memory medium may be located remotely with respect to the physical location of the one or more processors and controller. For instance, the one or more processors of controller may access a remote memory (e.g., server), accessible through a network (e.g., internet, intranet and the like).

As used throughout the present disclosure, the term “sample” generally refers to a substrate formed of a semiconductor or non-semiconductor material (e.g., thin filmed glass, ceramic, or the like). For example, a semiconductor or non-semiconductor material may include, but is not limited to, monocrystalline silicon, gallium arsenide, indium phosphide, organic substrate such as Ajinomoto Build-up film (ABF), or a glass material. A sample may include one or more layers. For example, such layers may include, but are not limited to, a resist (including a photoresist), a dielectric material, a conductive material, and a semiconductive material. Many different types of such layers are known in the art, and the term sample as used herein is intended to encompass a sample on which all types of such layers may be formed. One or more layers formed on a sample may be patterned or un-patterned. For example, a sample may include a plurality of dies, each having repeatable patterned features. Formation and processing of such layers of material may ultimately result in completed devices. Many different types of devices may be formed on a sample, and the term sample as used herein is intended to encompass a sample on which any type of device known in the art is being fabricated. Further, for the purposes of the present disclosure, the term sample, panel, and wafer should be interpreted as interchangeable. In addition, for the purposes of the present disclosure, the terms patterning device, mask and reticle should be interpreted as interchangeable.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A repair system comprising:
a light source, wherein the light source is configured to generate illumination;
a laser generator, wherein the laser generator is configured to generate laser light;
a two-axis scanner, wherein the two-axis scanner steers the laser light;
a sample stage, wherein the sample stage is configured to support a sample;
an objective lens, wherein the laser light is configured to pass through the objective lens to the sample to perform a repair of a defect located at a defect location on the sample;
a detector, wherein the detector is configured to generate image data associated with the sample based on collected light, wherein the collected light reflects from the sample, through the objective lens, to the detector; and
a controller comprising one or more processors configured to execute program instructions maintained on a memory medium, the program instructions causing the controller to:
change one or more optical properties of at least one of the illumination, the laser light, or the collected light during the repair of the defect.

2. The repair system of claim 1, wherein the defect is an excess material defect comprising an excess solid material; wherein the laser light repairs the excess material defect by ablating the excess solid material.

3. The repair system of claim 1, wherein the program instructions cause the controller to change the one or more optical properties during the repair of the defect based on feedback from the image data.

4. The repair system of claim 1, wherein the one or more optical properties of the laser light comprise at least a spot size of the laser light, wherein the repair system is configured to perform a first stage of repair of the defect using a first spot size and a second stage of repair of the defect using a second spot size.

5. The repair system of claim 4, wherein the repair system changes between the first spot size and the second spot size by changing at least one of the objective lens, a magnification of the objective lens, a focus position, a position of a variable beam expander, or an iris diameter.

6. The repair system of claim 5, comprising an objective lens turret comprising a plurality of objective lenses, wherein the objective lens is one of the plurality of objective lenses, wherein the controller is configured to cause the objective lens turret to change between the plurality of objective lenses.

7. The repair system of claim 5, comprising a zoom motor, wherein the zoom motor is coupled to the objective lens, wherein the zoom motor controls the magnification of the objective lens.

8. The repair system of claim 4, wherein the program instructions cause the controller to change the spot size during the repair of the defect based on a closed loop condition comprising a sharpness of the defect in the image data.

9. The repair system of claim 1, wherein the one or more optical properties of the laser light comprise at least a fluence of the laser light.

10. The repair system of claim 1, wherein the one or more optical properties of the illumination comprise at least one of an incidence angle of the illumination or a collection angle of illumination reflected from the sample.

11. The repair system of claim 1, wherein the one or more optical properties of the laser light comprise at least a waist position of the laser light.

12. The repair system of claim 11, wherein the controller is configured to direct the waist position of the laser light to follow along a height profile of the defect.

13. The repair system of claim 12, wherein the one or more optical properties of the laser light comprise the waist position and a fluence of the laser light.

14. The repair system of claim 1, wherein the controller is configured to preset the one or more optical properties based on a finest feature in a design file.

15. The repair system of claim 1, wherein the controller is configured to preset the one or more optical properties based on an expected size of the defect according to a design resolution in a design file at the defect location.

16. The repair system of claim 15, wherein the controller presets the one or more optical properties before the detector generates the image data.

17. The repair system of claim 1, wherein the controller changes the one or more optical properties on a pulse-to-pulse basis.

18. The repair system of claim 1, wherein the memory medium maintains a design file and a defect report, wherein the design file comprises two-dimensional data, wherein the repair system is configured to iteratively reach the defect location, acquire the image data at the defect location, identify the defect, set the one or more optical properties based on the defect identified, and repair the defect for each known defect in the defect report.

19. The repair system of claim 1, wherein the memory medium maintains a design file and a defect report, wherein the design file comprises two-dimensional data, wherein the repair system is configured to iteratively check a design resolution in the design file at the defect location, preset the one or more optical properties according to the design resolution in the design file at the defect location, reach the defect location, acquire the image data at the defect location, identify the defect in the image data, set the one or more optical properties based on the defect identified if needed, and repair the defect for each known defect in the defect report.

20. The repair system of claim 1, wherein the memory medium maintains a design file and a defect report, wherein the design file comprises two-dimensional data, wherein the repair system is configured to iteratively reach the defect location on the sample, acquire the image data at the defect location, identify the defect, set the one or more optical properties based on the defect identified, perform a first stage of defect repair, change the one or more optical properties, and perform a second stage of repair for each known defect in the defect report.

21. The repair system of claim 20, wherein the one or more optical properties comprise at least a spot size of the laser light, wherein the controller is configured to set the spot size of the laser light to a first spot size, wherein the repair system performs the first stage of defect repair using the first spot size, wherein the controller changes the spot size of the laser light to a second spot size, wherein the repair system performs the second stage using the second spot size.

22. The repair system of claim 21, wherein the repair system scans the laser light along a center of the defect in the first stage, wherein the repair system scans the laser light along an exterior perimeter of the defect in the second stage.

23. The repair system of claim 22, wherein the repair system does not scan the laser light along the exterior perimeter in the first stage.

24. The repair system of claim 1, wherein the defect is disposed between a pair of conductors, wherein a spot size of the laser light is changed based on at least one of a space width between the pair of conductors and a line width of at least one of the pair of conductors.

25. The repair system of claim 24, wherein the repair system is configured to find at least one of the space width or the line width based on at least one of a design file or the image data.

26. The repair system of claim 1, wherein the collected light reflecting from the sample comprises light emitted by the sample following excitation by at least one of the illumination or the laser light.

27. The repair system of claim 1, wherein the illumination and the laser light are configured to pass through the objective lens to the sample.

28. The repair system of claim 1, wherein the illumination is directed to the sample in a darkfield configuration.

29. A method comprising:
changing one or more optical properties of at least one of an illumination, a laser light, or a collected light during a repair of a defect by a controller of a repair system, the repair system comprising a light source, wherein the light source is configured to generate the illumination; a laser generator, wherein the laser generator is configured to generate the laser light; a two-axis scanner, wherein the two-axis scanner steers the laser light; a sample stage, wherein the sample stage is configured to support a sample; an objective lens, wherein the laser light is configured to pass through the objective lens to the sample to perform the repair of the defect located at a defect location on the sample; a detector, wherein the detector is configured to generate image data associated with the sample based on the collected light, wherein the collected light reflects from the sample, through the objective lens, to the detector; and the controller comprising one or more processors configured to execute program instructions maintained on a memory medium, the program instructions causing the controller to change the one or more optical properties.
